(19) United States
(12) Patent Application Publication
(10) Pub. No.: US 2015/0371946 A1
(43) Pub. Date: Dec. 24, 2015

(54) SEMICONDUCTOR DEVICE AND METHOD FOR MANUFACTURING SAME

(71) Applicant: PS4 Luxco S.a.r.l., Luxembourg (LU)

(72) Inventor: Kazuhiro Segawa, Tokyo (JP)

(21) Appl. No.: 14/766,708

(22) PCT Filed: Feb. 6, 2014
(86) PCT No.: PCT/JP2014/052710

§ 371 Date: Aug. 7, 2015

(30) Foreign Application Priority Data
Feb. 8, 2013 (JP) 2013-023193

(51) Int. Cl. H01L 23/522; H01L 21/768; H01L 21/762; H01L 27/108; H01L 29/06

(52) U.S. Cl. CPC H01L 23/5225; H01L 27/108; H01L 29/0649; H01L 21/76224; H01L 21/76801; H01L 21/76877; H01L 27/10847

(57) ABSTRACT

In the present invention, in a twin plug-forming step, a conductive material is removed so as to form a groove for separating a diffusion layer (29), a diffusion layer-separating insulating film (30) is implanted so as to separate a diffusion layer, and contact plugs (25b) and (25c) are separated. In the twin plug-forming step, a second conductive material is implanted in a contact hole surrounded by a bit line (16) between word lines (10b) and (10d), and is separated in a second direction. The conductive material was implanted in a dummy word line in the related art.

### TECHNICAL FIELD

The present invention relates to a semiconductor device and a method for manufacturing same.

### BACKGROUND

Methods for forming miniature contact plugs are being investigated as semiconductor devices becoming smaller. Among these, Patent Document 1 describes a method in which a conductive material formed in a large contact hole in advance is split to achieve miniaturization, and this method is very effective because there is a large processing margin.

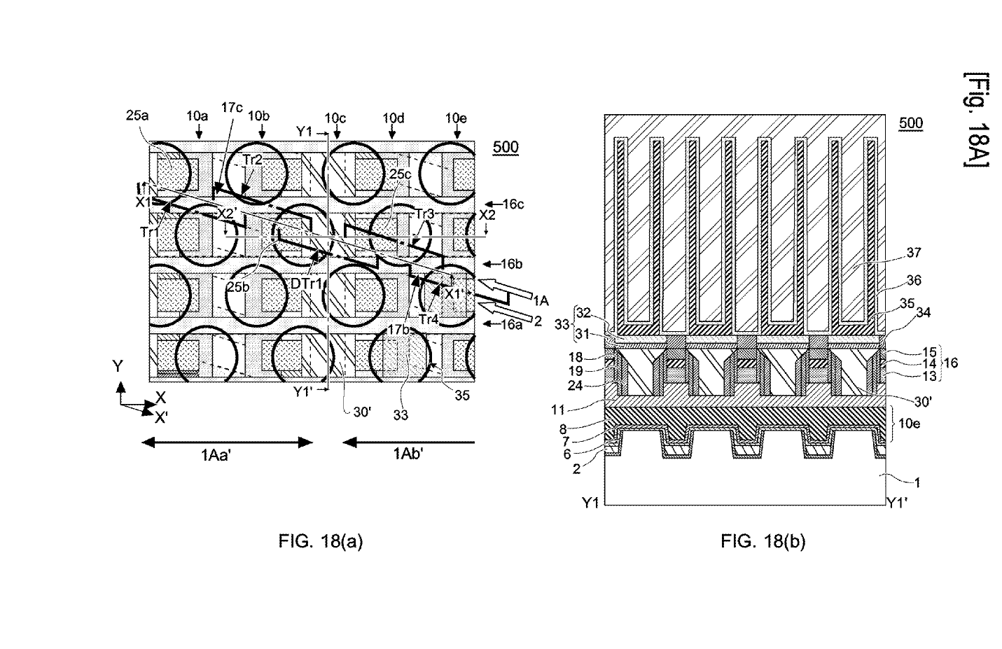

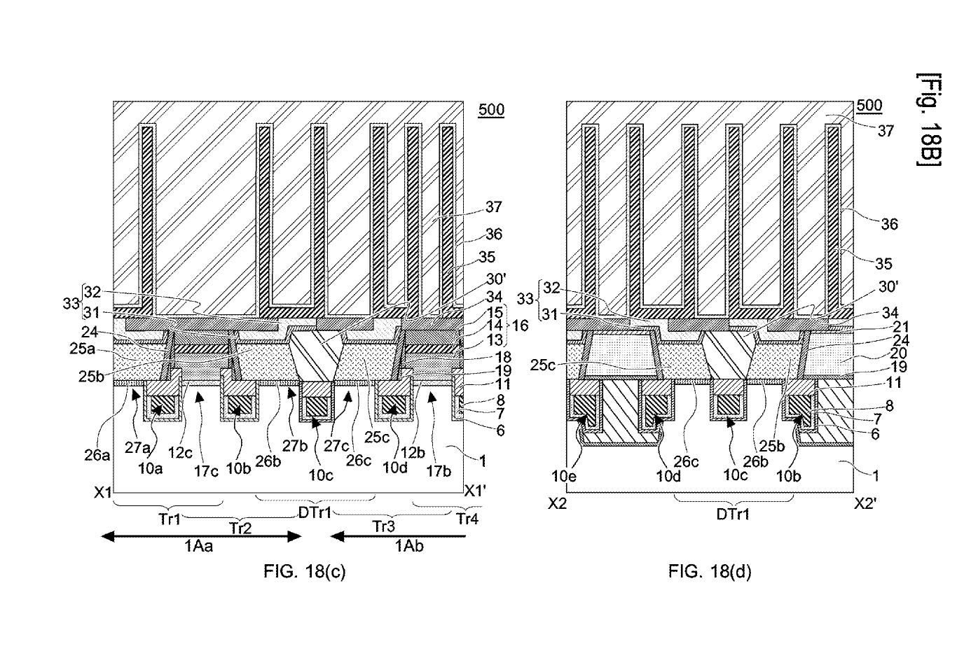

FIG. 18 shows the structure of a semiconductor device 500 according to Patent Document 1. The semiconductor device 500 according to this conventional example is a DRAM; FIG. 18(a) is a plan view, FIG. 18(b) is a view in the cross section Y1-Y1′ in FIG. 18(a), FIG. 18(c) is a view in the cross section X1-X1′ in FIG. 18(a), and FIG. 18(d) is a view in the cross section X2-X2′ in FIG. 18(a). It should be noted that in the present specification, fig. X(a)-X(d) may be referred to collectively as fig. X.

The semiconductor device 500 according to this conventional example will be described first of all with reference to FIG. 18.

The semiconductor device 500 constitutes a DRAM memory cell. A plurality of element isolation regions 2 extending continuously in the X′-direction and a plurality of active regions 1A likewise extending continuously in the X′-direction are disposed at equal intervals and an equal pitch alternately in the Y-direction on a semiconductor substrate 1. The element isolation regions 2 are formed by an element isolation insulating film embedded in a trench. The following are disposed extending continuously in the Y-direction across the plurality of element isolation regions 2 and the plurality of active regions 1A: a first embedded word line (referred to below as a first word line) 10a, a second embedded word line (referred to below as a second word line) 10b, a third embedded word line (referred to below as a third word line) 10d, and a fourth embedded word line (referred to below as a fourth word line) 10e. Furthermore, a first embedded dummy word line (referred to below as a first dummy word line) 10c is disposed in such a way as to lie between the second word line 10b and the third word line 10d. The first dummy word line 10c has the function of providing element isolation between cell transistors Tr2-Tr3 which are adjacent in the direction of extension of the respective active regions 1A by keeping a parasitic transistor DTr1 in an OFF state, and also of dividing continuous strip-like active regions 1A into a plurality of independent active regions. Specifically, the active region 1A positioned to the left of the first dummy word line 10c forms a first active region 1Aa′, while the active region 1A positioned to the right forms a second active region 1Ab′.

The first active region 1Aa′ comprises: a second capacitance contact region 27b disposed adjacently to the left of the first dummy word line 10c; the second word line 10b which is disposed adjacent to the second capacitance contact region 27b; a first bit line contact region 17c disposed adjacent to the second word line 10b; the first word line 10a disposed adjacent to the first bit line contact region 17c; and a first capacitance contact region 27a disposed adjacent to the first word line 10a. The first capacitance contact region 27a, first word line 10a and first bit line contact region 17c form the first cell transistor Tr1, and the first bit line contact region 17c, second word line 10b and second capacitance contact region 27b form the second cell transistor Tr2.

The second active region 1Ab′ comprises: a third capacitance contact region 27c disposed adjacently to the right of the first dummy word line 10c; the third word line 10d disposed adjacent to the third capacitance contact region 27c; a second bit line contact region 17b disposed adjacent to the third word line 10d; the fourth word line 10e disposed adjacent to the second bit line contact region 17b; and a fourth capacitance contact region (not depicted) disposed adjacent to the fourth word line 10e. The third capacitance contact region 27c, third word line 10d and second bit line contact region 17b form a third cell transistor Tr1, and the second bit line contact region 17b, fourth word line 10e and fourth capacitance contact region which is not depicted form a fourth cell transistor Tr4.

The memory cell according to this conventional example is constructed by arranging a plurality of the first active region 1Aa and second active region 1Ab structures in the X-direction with the first dummy word line 10c therebetween.

Trenches for word lines also serving as gate electrodes of the transistor are provided in the semiconductor substrate 1. The first word line 10a, second word line 10b, dummy word line 10c, third word line 10d and fourth word line 10e are provided at the bottom of the respective trenches and are formed by a barrier film 7 and a metal film 8 such as tungsten with the interposition of a gate insulating film 6 covering the inner surface of each word line trench. Here, for the sake of convenience, the word lines passing through the first active region 1Aa′ are referred to as the first word line 10a and second word line 10b, and the word lines passing through the second active region 1Ab′ are referred to as the third word line 10d and fourth word line 10e, but each active region comprises two word lines and the dummy word line is disposed between the active regions. A cap insulating film 11 is provided by covering each word line and filling the respective trenches. A semiconductor pillar positioned to the left of the first word line 10a forms the first capacitance contact region 27a, and an impurity diffusion layer 26a forming either a source or drain is provided on the upper surface thereof. A semiconductor pillar positioned between the first word line 10a and the second word line 10b forms the third BL contact region 17c, and an impurity diffusion layer 12c forming the other of the source or drain is provided on the upper surface thereof. Furthermore, a semiconductor pillar positioned to the right of the second word line 10b forms the second capacitance contact region 27b, and an impurity diffusion layer 26b forming either a source or a drain is provided on the upper surface thereof. In addition, a semiconductor pillar positioned to the left of the third word line 10d forms the third capacitance contact region 27c, and an impurity diffusion layer 26c forming either a source or a drain is provided on the upper surface thereof. A semiconductor pillar positioned to the right of the third word line 10d then forms the second BL contact region 17b, and an impurity diffusion layer 12b forming the other of the source or drain is provided on the upper surface thereof.

The second bit line (BL) 16b which is connected to the second impurity diffusion layer 17b in the second BL contact region 12b is provided on the cap insulating film 11 covering the upper surface of each word line, and the third bit line (BL) 16c which is connected to the third impurity diffusion layer 17c in the third BL contact region 12c is also provided thereon. In each bit line, a polysilicon layer 13 including a bit contact plug connected to an impurity diffusion layer, and a bit metal layer 14 formed thereon are provided, and a cover insulating film 15 is further provided on the upper surface thereof. Side walls 18 are provided on the lateral walls of each bit line, and a liner insulating film 19 is provided over the whole surface in such a way as to cover the bit lines. An embedded insulating film 20 filling the space of the recess formed between adjacent BL is provided on the liner insulating film 19. A capacitance contact 25 is provided passing through the embedded insulating film 20 and the liner film 19. The capacitance contact 25 connects first, second and third capacitance contact plugs 25a, 25b, 25c to the first, second and third capacitance contact regions 27a, 27b, 27c. The cap insulating film 11 on the dummy word line 10c comprises an isolation insulating film 30′ which isolates the second and third capacitance contact plugs 25b, 25c. The second capacitance contact plug 25b in the first element isolation region 1Aa′ and the third capacitance contact plug 25c in the second element isolation region 1Ab′ which are element-isolated by the dummy word line 10c constitute twin plugs which are formed by dividing a single large contact plug 25, and the isolation insulating film 30′ is provided at the divided surface thereof. Respective contact pads 33 are connected to the upper parts of the first, second and third capacitance contact plugs 25a, 25b, 25c. A stopper film 34 is provided in such a way as to cover the capacitance contact pads 33. A lower electrode 35 is provided on the capacitance contact pads 33. A capacitor is formed by providing a capacitance insulating film 36 continuously covering the surfaces of the inner walls and outer walls of the lower electrode 35, and by providing an upper electrode 37 on the capacitance insulating film 36.

### PATENT DOCUMENTS

Patent Document 1: JP 2011-243960 A

### SUMMARY OF THE INVENTION

### Problem to be Solved by the Invention

The abovementioned prior art relates to a structure in which element isolation in the first active region 1Aa′ and the second active region 1Ab′ is achieved by means of a field shield afforded by the first dummy word line 10c. The pitch therefore becomes narrower as miniaturization progresses further, element isolation cannot be adequately achieved, and there are a greater number of interference and disturbance defects between adjacent cells, among other things, so there is room for further improvement.

### Means for Solving the Problem

According to the present invention, an increase in PCBH defects is suppressed by replacing the first dummy word line 10c with an insulating layer.

That is to say, a mode of embodiment of the present invention provides a semiconductor device comprising:

a plurality of element isolation regions extending in a first direction on a semiconductor substrate;

an active region lying between the element isolation regions and extending in the first direction;

a plurality of trenches disposed at predetermined intervals and extending in a second direction intersecting the first direction;

a pair of embedded word lines embedded inside two adjacent trenches with one of the abovementioned trenches interposed;

a bit line which extends in a third direction different than the first and second directions and is connected to an active region between the pair of embedded word lines;

a contact which is connected to an active region facing an active region to which the bit line is connected with the pair of embedded word lines interposed; and

a diffusion layer isolation insulating film which is embedded in the trench between the pair of embedded word lines, and insulates and isolates the contact on both sides of said trench and a diffusion layer in the active region connected to the contact.

Furthermore, a different mode embodiment of the present invention provides a method for manufacturing a semiconductor device comprising the following steps:

a step in which a plurality of element isolation regions extending in a first direction are formed on a semiconductor substrate, and an active region extending in the first direction is defined between the element isolation regions;

a step in which two adjacent pairs of word line trenches extending in a second direction intersecting the first direction, and a diffusion layer isolation trench between the pairs of word line trenches are formed on the semiconductor substrate with a predetermined gap therebetween as a plurality of trenches which are shallower than the element isolation regions, and the active region is divided into a first portion lying between the two word line trenches, and a second portion lying between the word line trench and the diffusion layer isolation trench;

a step in which a first conductive material is embedded inside the plurality of trenches with a gate insulating film interposed;

a step in which the first conductive material is etched back as far as a position at a lower level than the surface of the semiconductor substrate, and a dummy word line is formed between the two pairs of word lines and the pair of word lines;

a step in which an insulating film which fills the trench on the word line and the dummy word line is formed;

a step in which a bit line which is connected to the first portion, extends in a third direction different than the first and second directions and comprises an upper insulating film is formed on the abovementioned insulating film;

a step in which a mask pattern extending in the second direction is formed on the two pairs of word lines, the active region in the second portion on both sides of the dummy word line is exposed, and a contact hole which is defined by the area between the bit lines and the area between the mask patterns is formed;

a step in which the contact hole is filled by embedding a second conductive material as far as a position at a lower level than the upper part of the mask pattern;

a step in which side walls are formed on the lateral walls of the mask pattern and the upper surface of the second conductive material on the dummy word line is exposed and opened;

a step in which the second conductive material is etched using the side walls as a mask, and the embedded insulating film at the upper part of the dummy word line is exposed;

a step in which the insulating film is removed by dry etching and the exposed first conductive material is further removed by wet etching to form a diffusion layer isolation trench;

a step in which a diffusion layer isolation insulating film is formed over the whole surface by filling the diffusion layer isolation trench; and

a step in which the diffusion layer isolation insulating film, the mask pattern and the second conductive material are etched back to the height level of the upper insulating film of the bit line, and a contact plug comprising the second conductive material which is divided in two by the diffusion layer isolation insulating film is formed inside the contact hole.

### Advantage of the Invention

According to a mode of embodiment of the present invention, element isolation using a conventional dummy word line is achieved by means of an insulating film having an equal width and formed as a single film with an isolation insulating film for isolating a twin plug, and as a result adequate element isolation can be achieved even if the word line pitch is narrowed, and it is possible to suppress an increase in the number of interference and disturbance defects between adjacent cells.

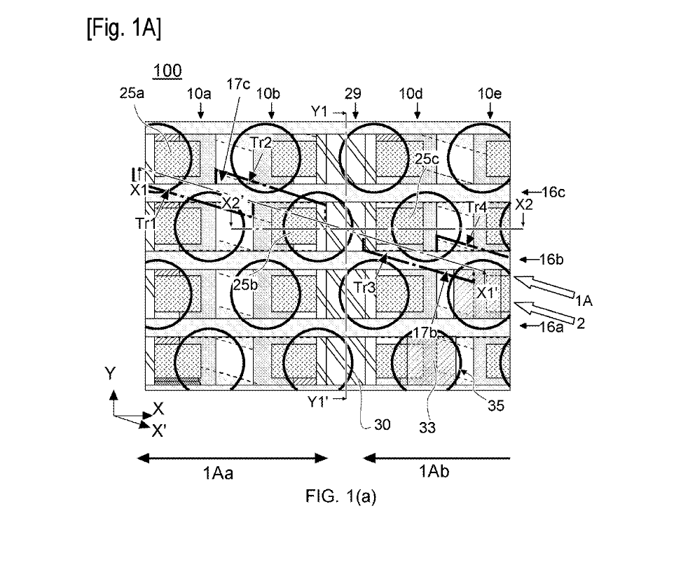

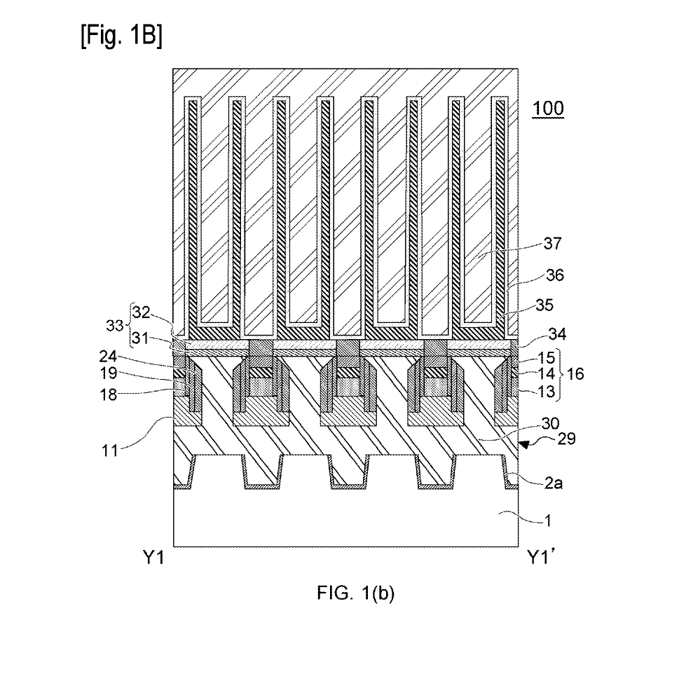

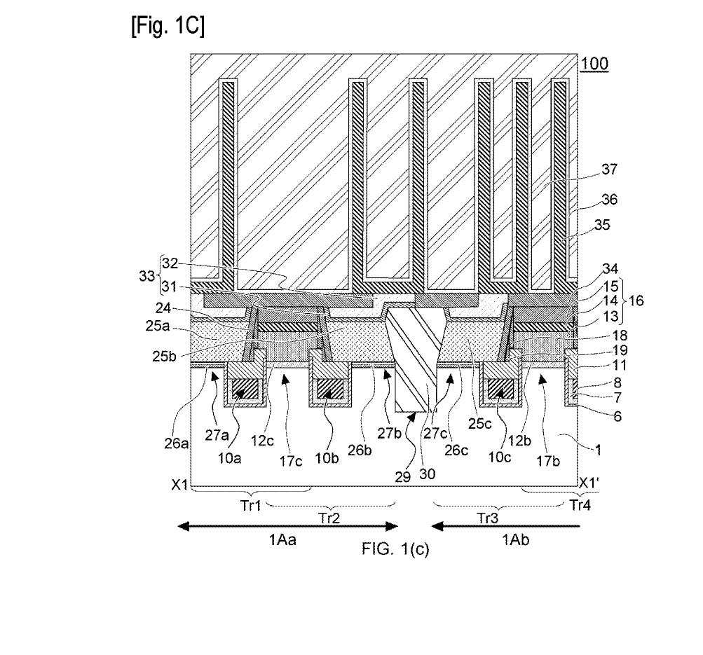

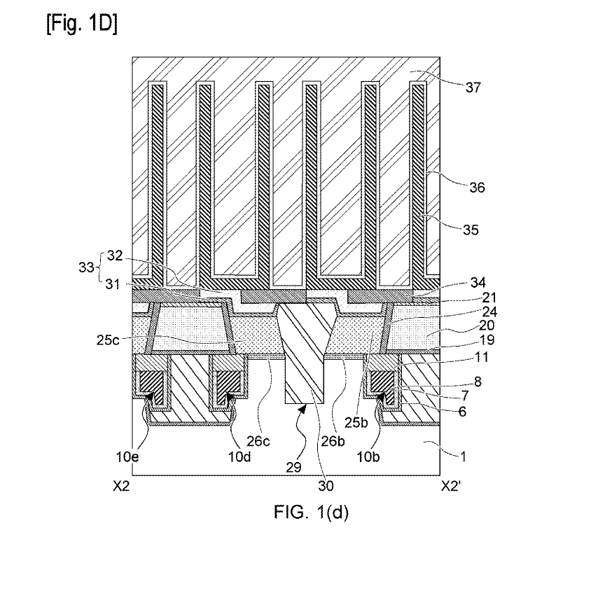

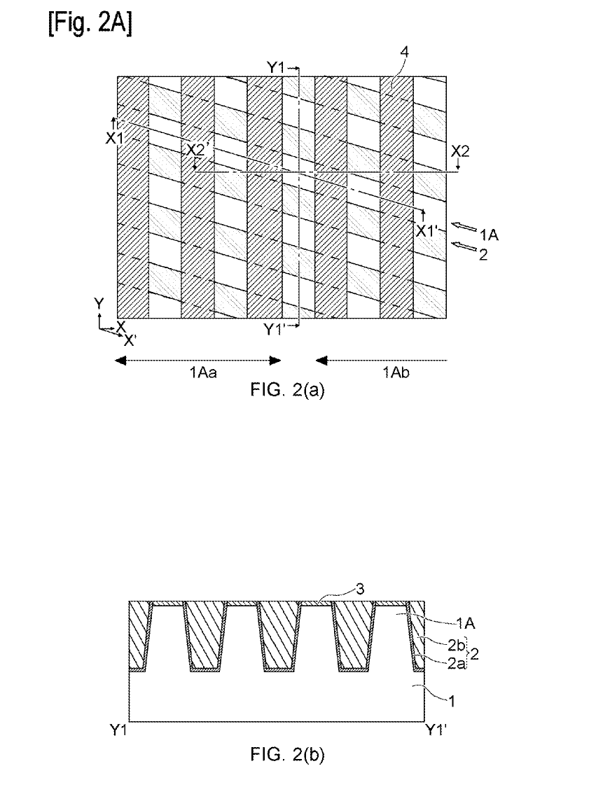

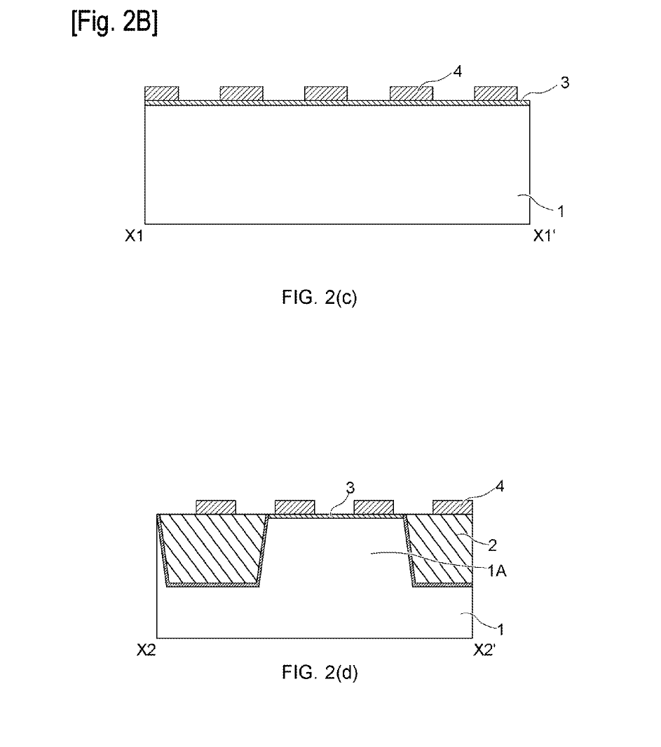

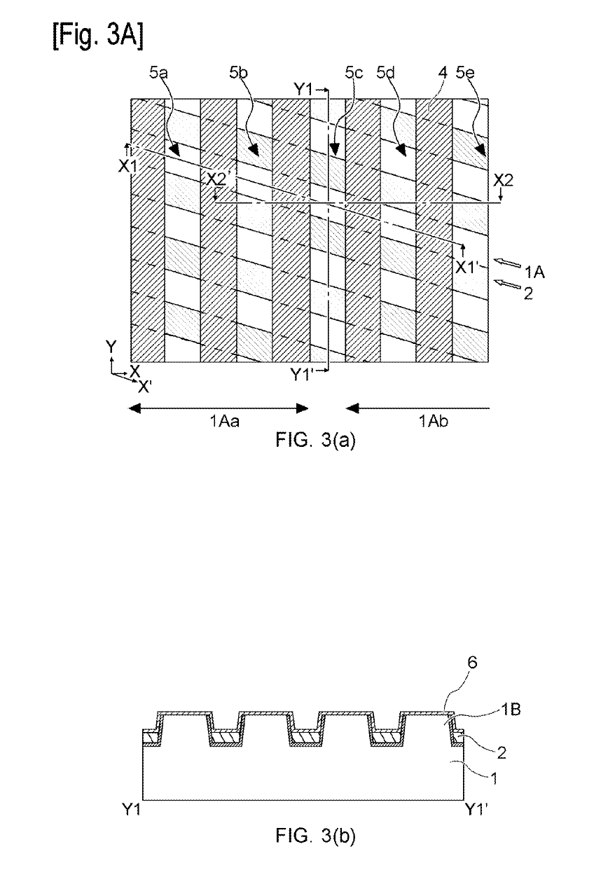

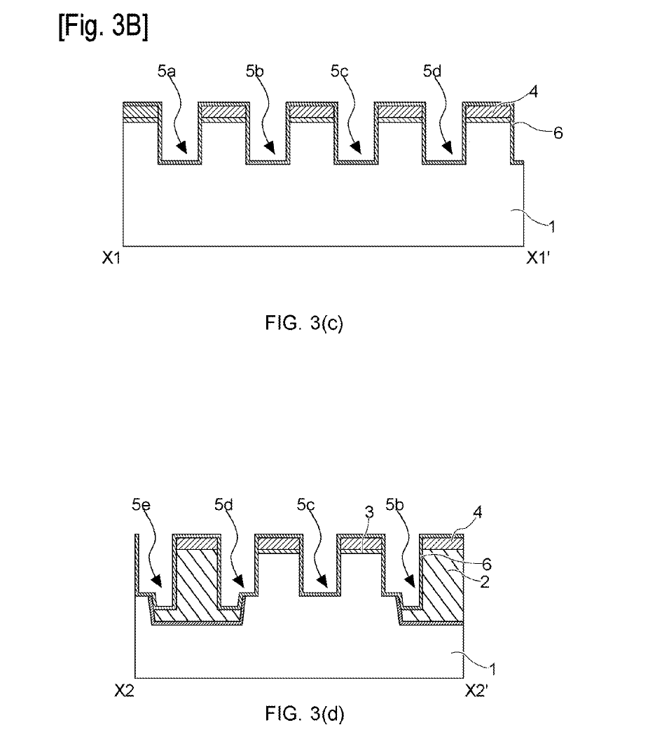

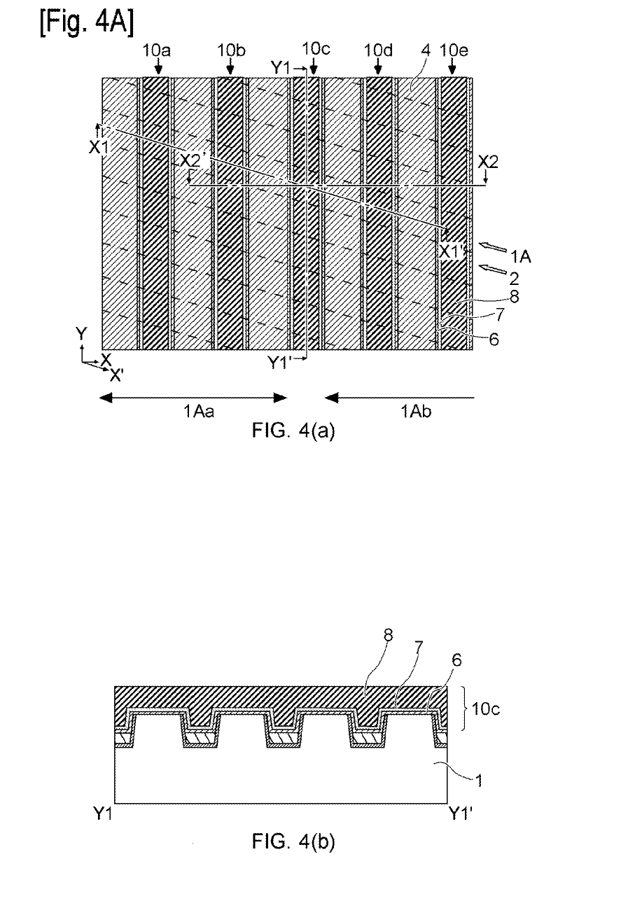

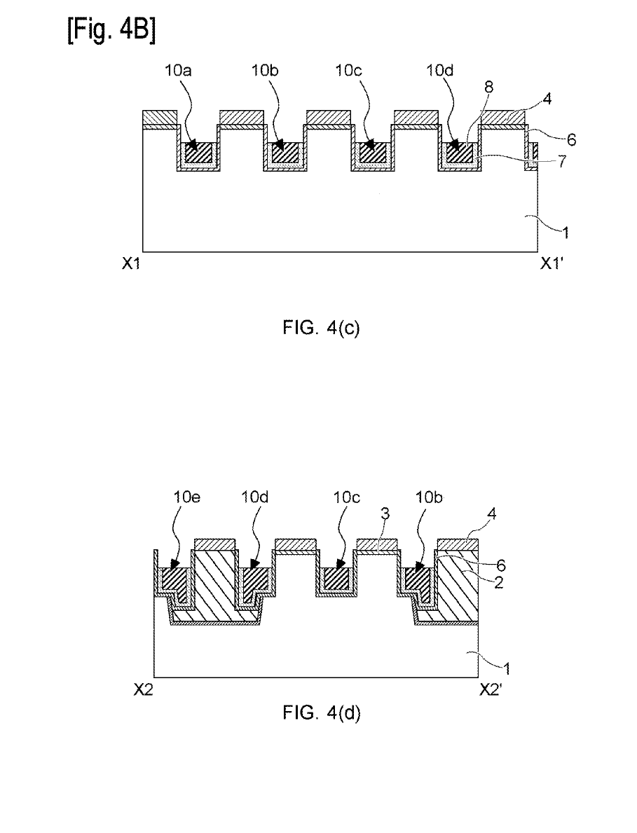

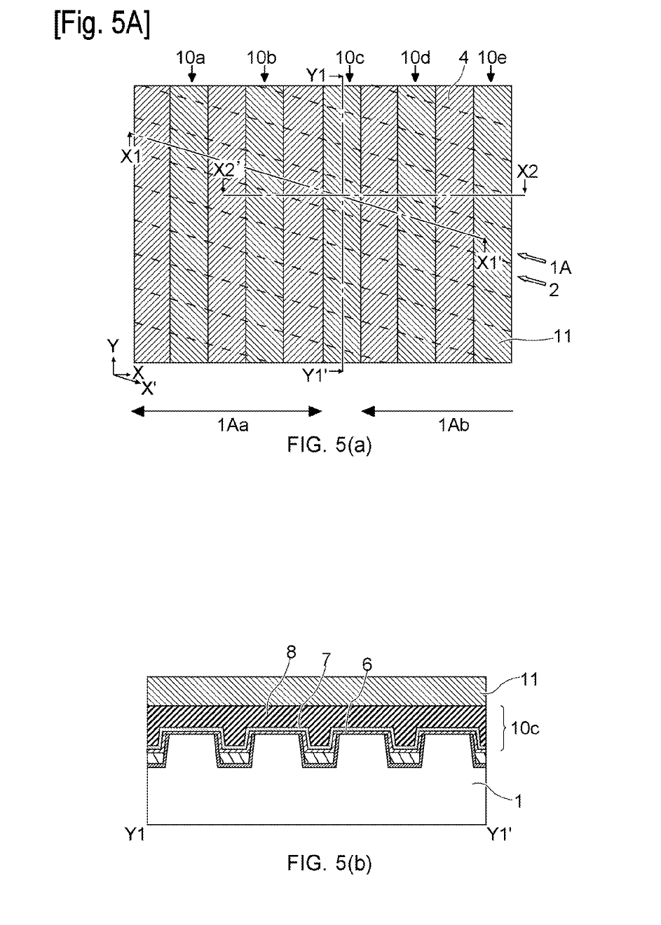

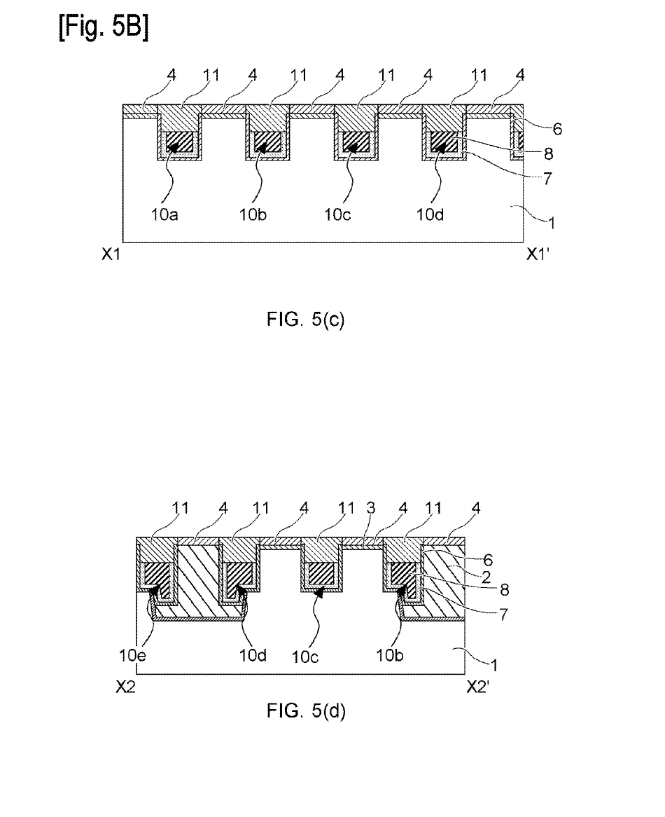

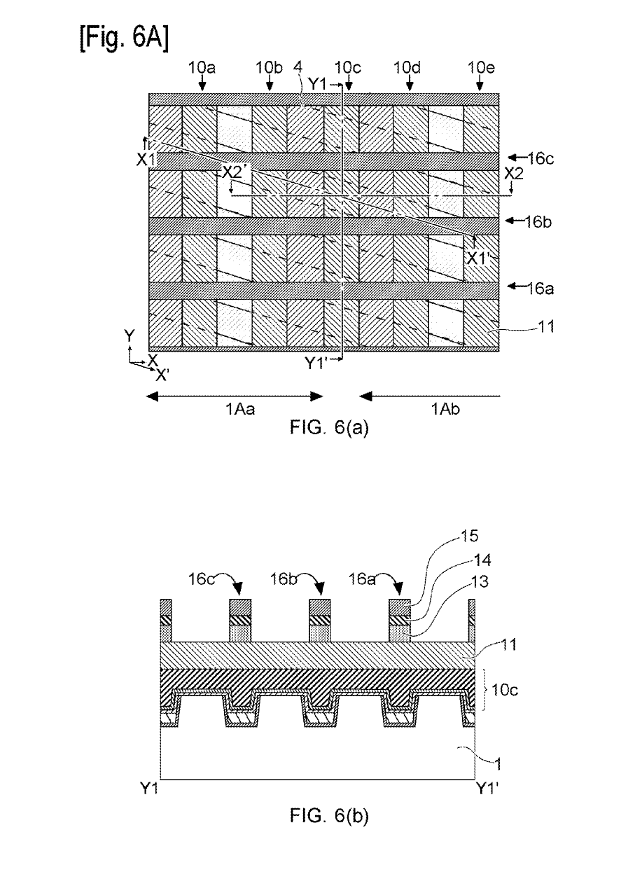

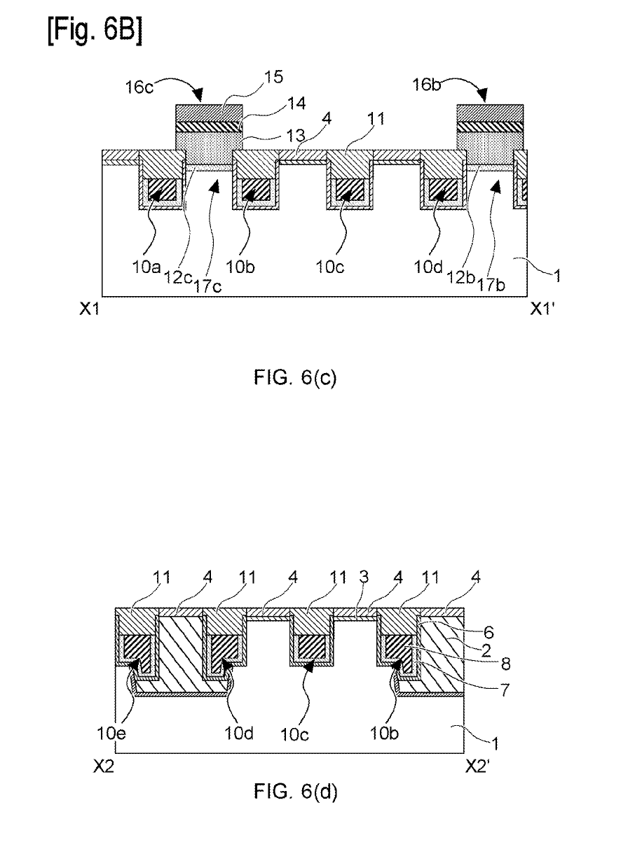

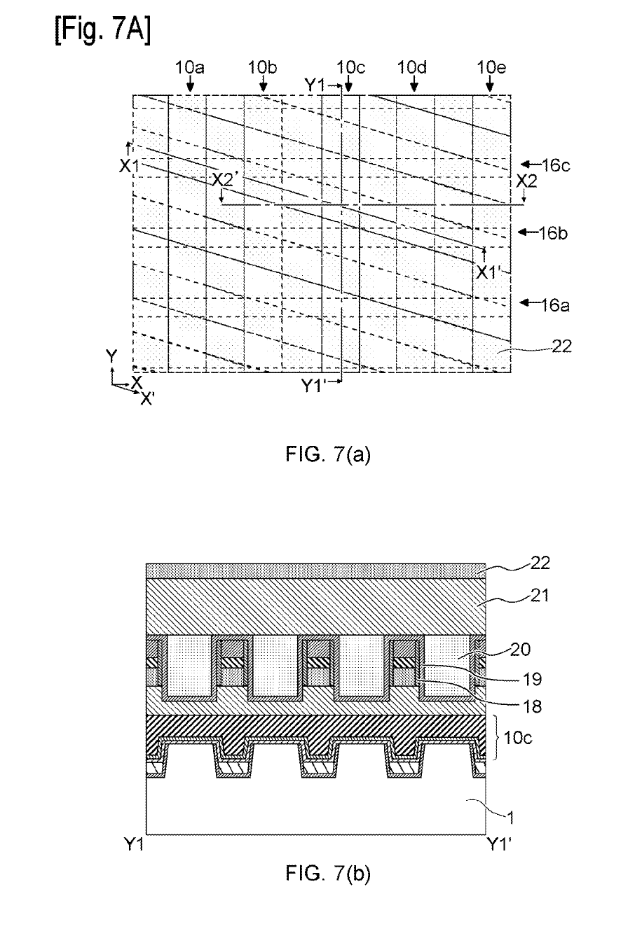

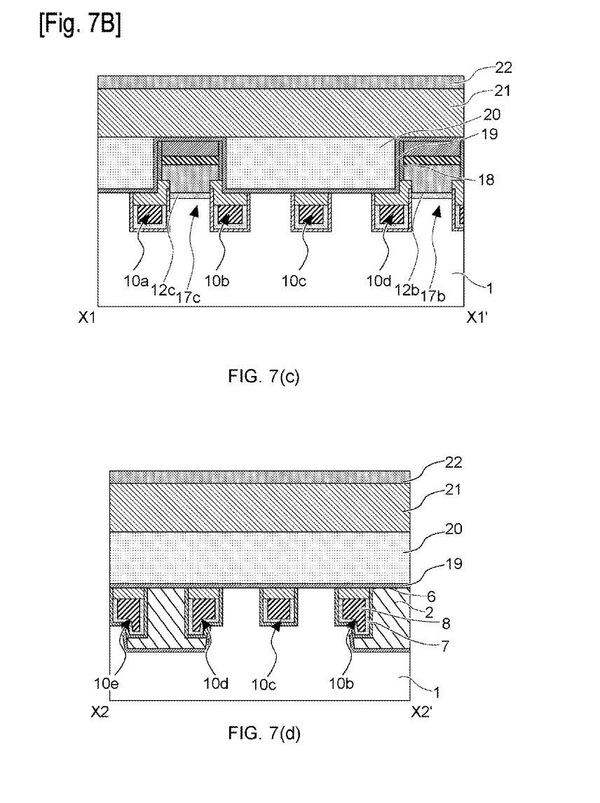

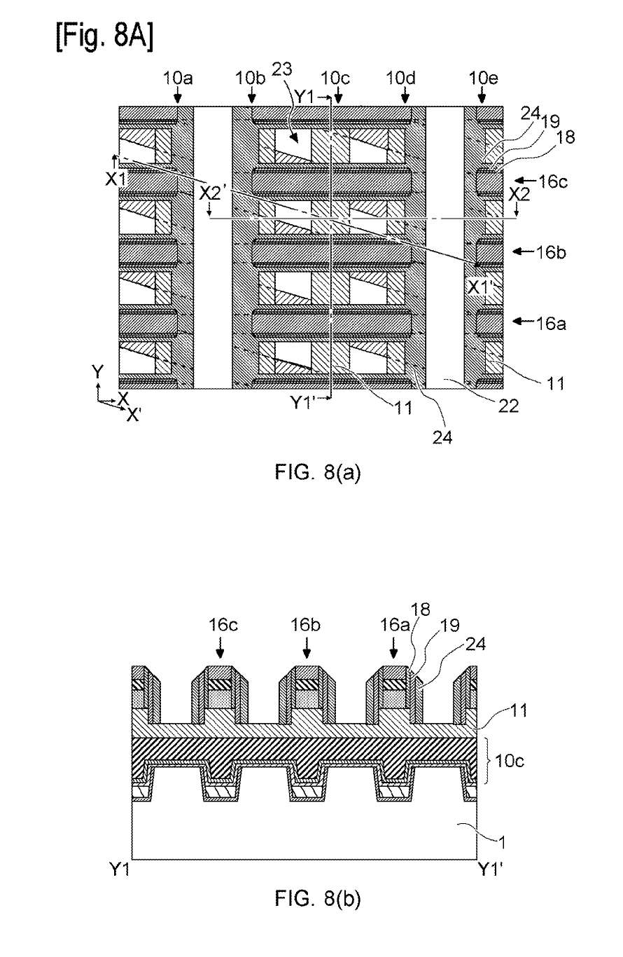

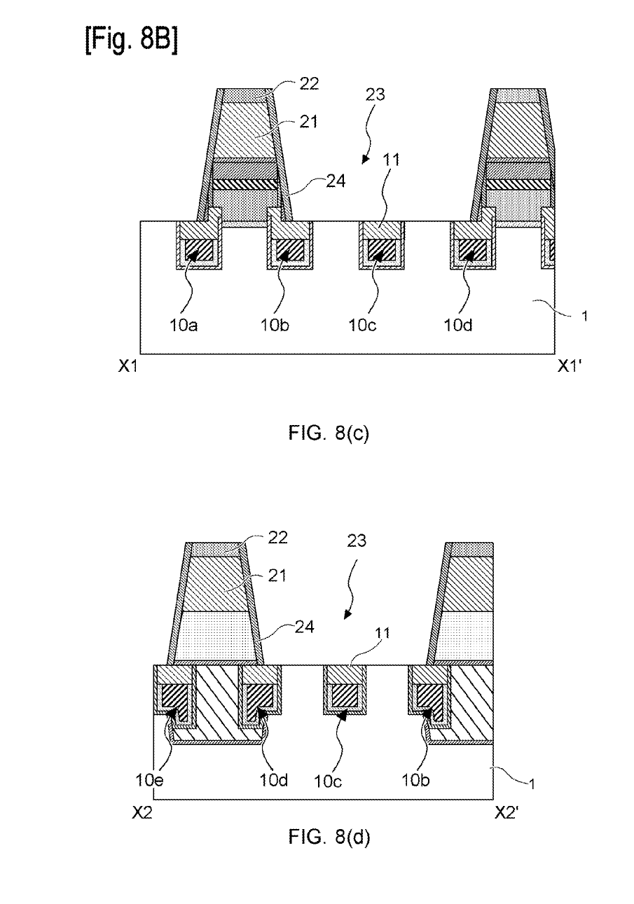

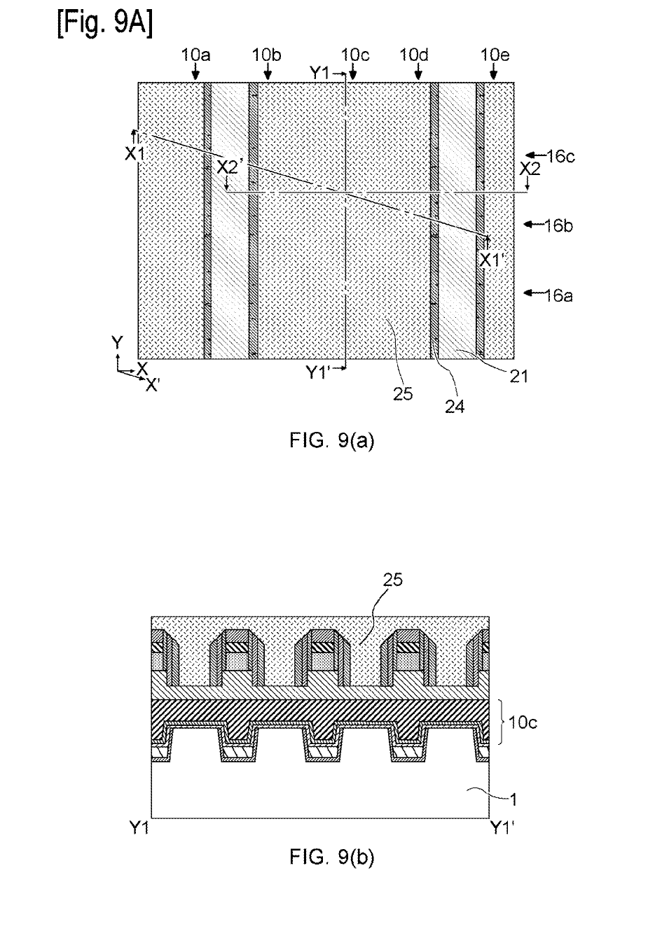

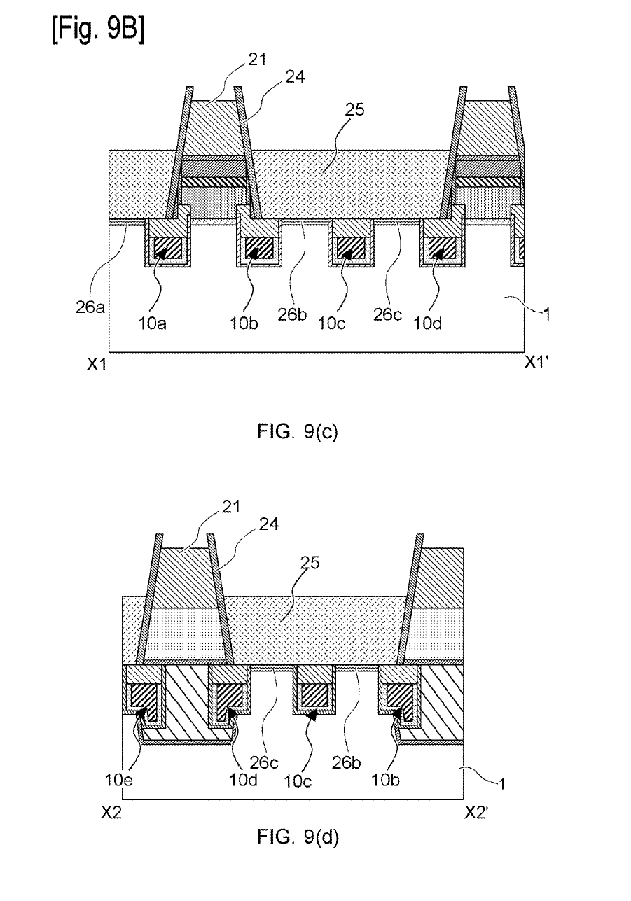

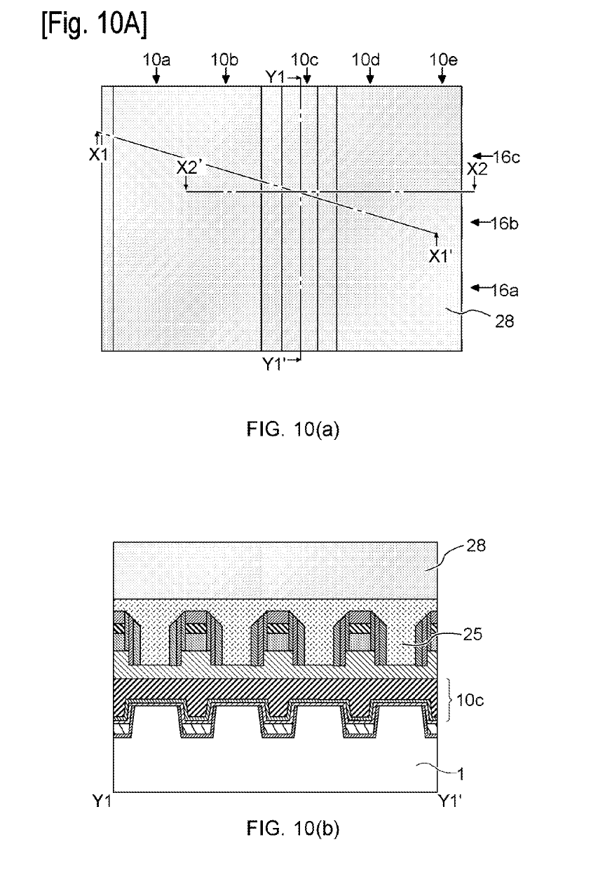

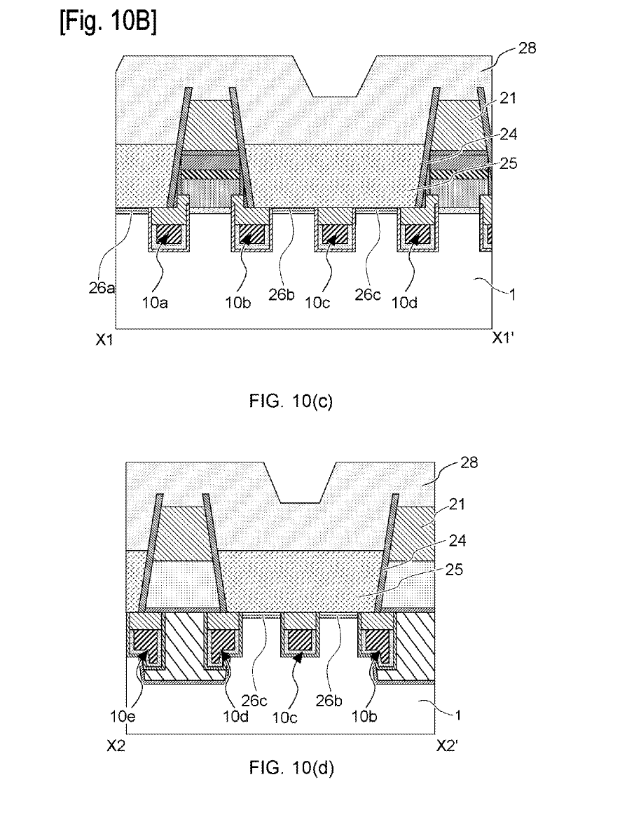

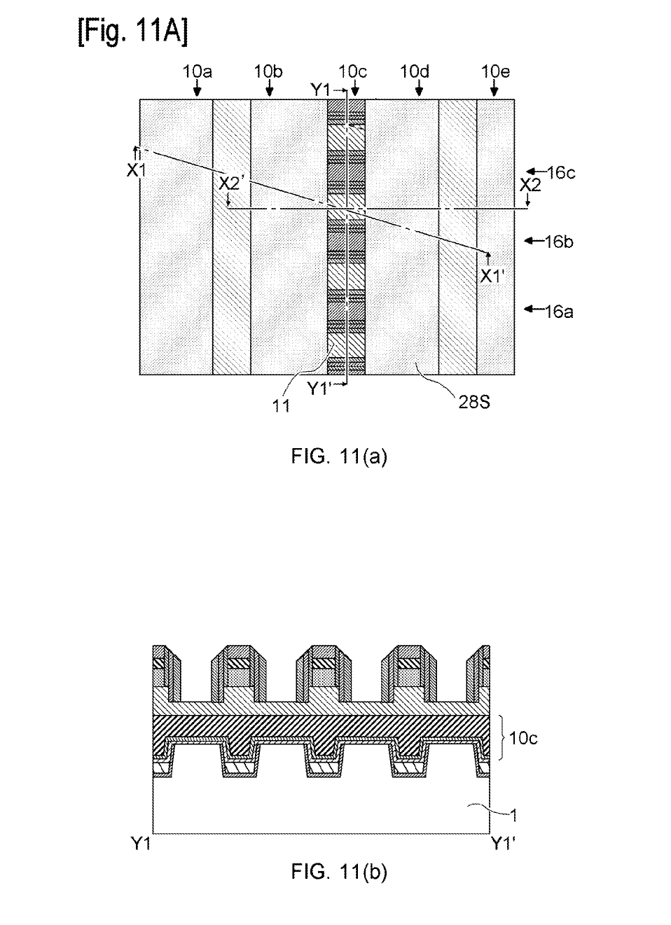

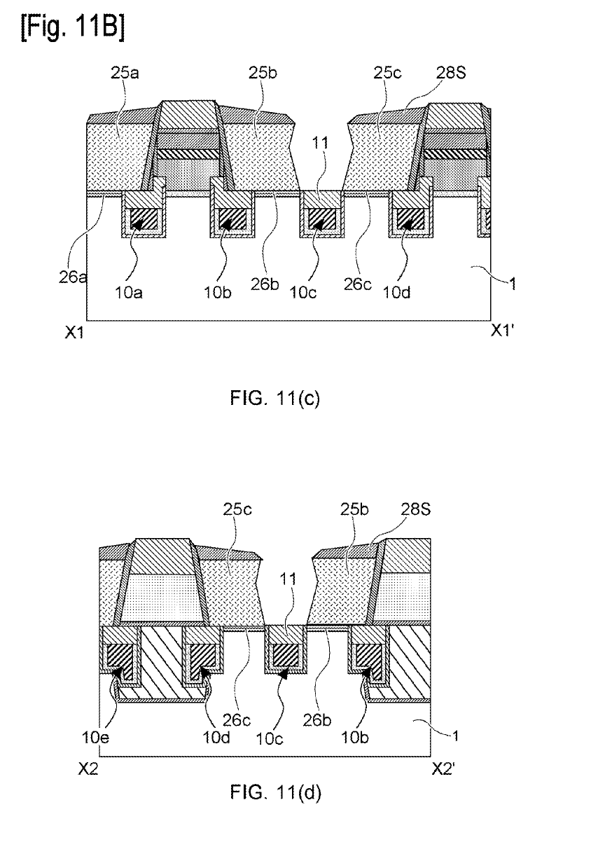

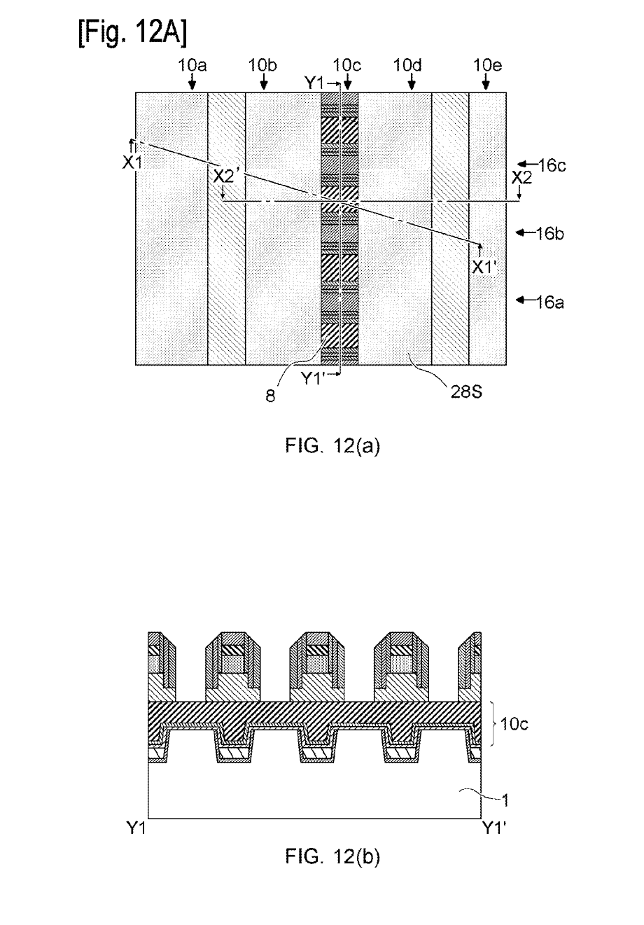

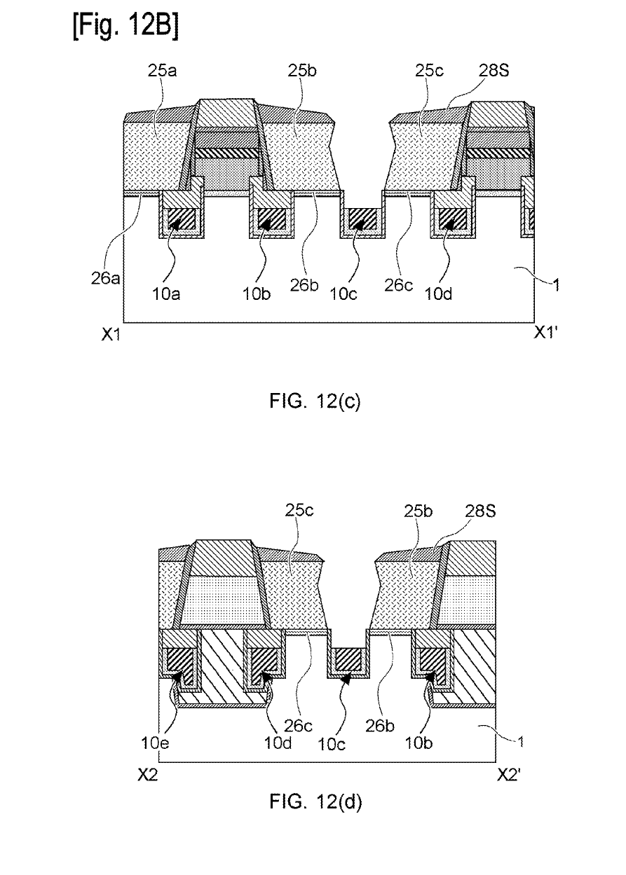

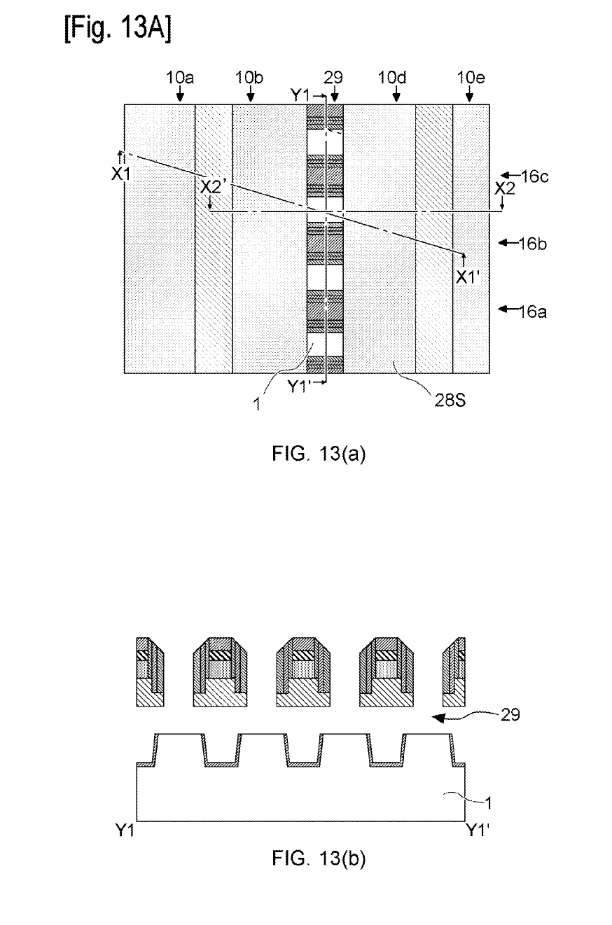

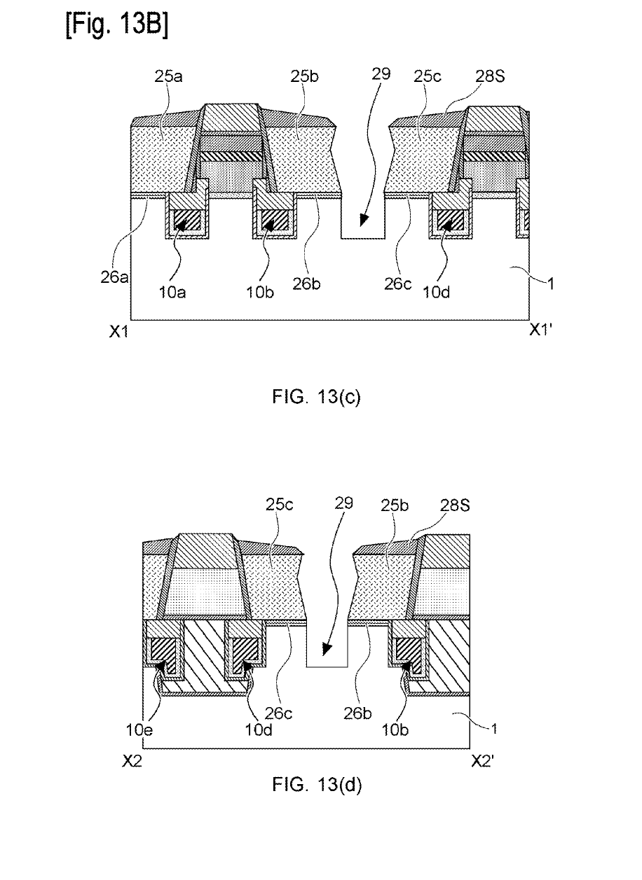

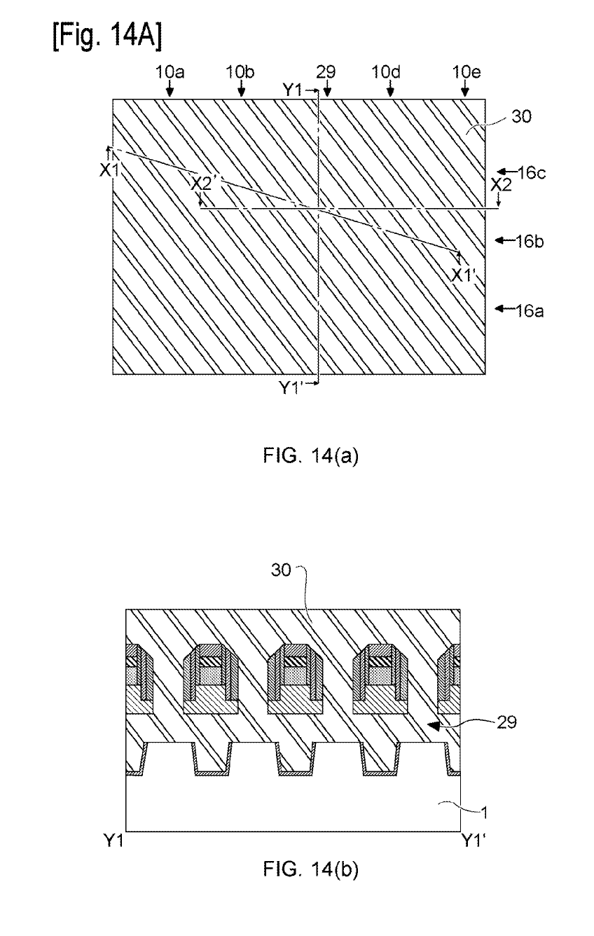

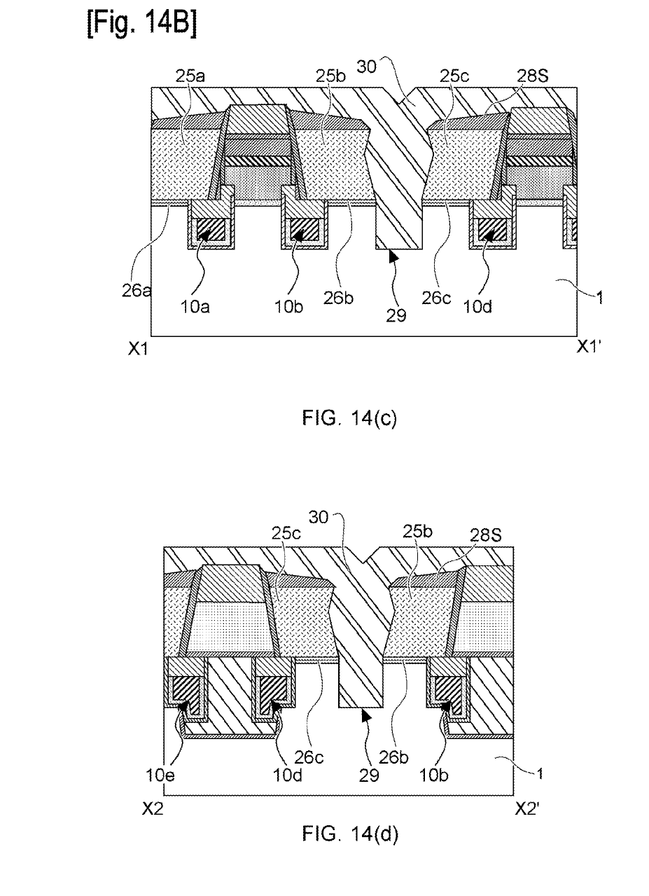

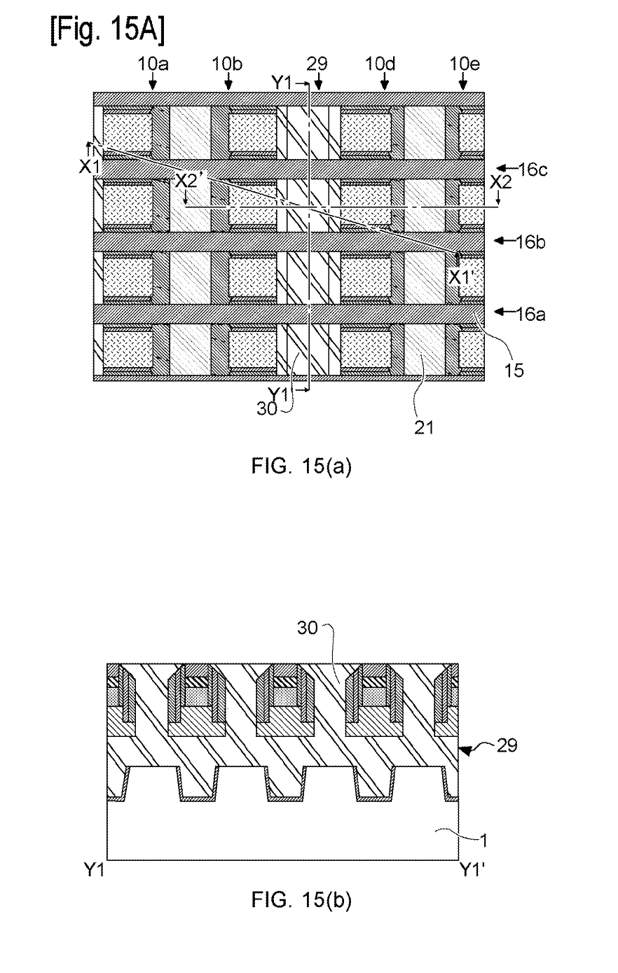

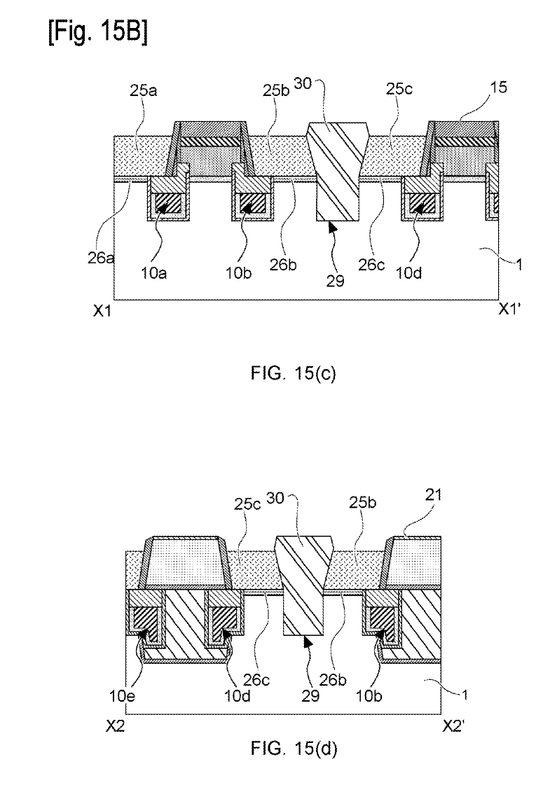

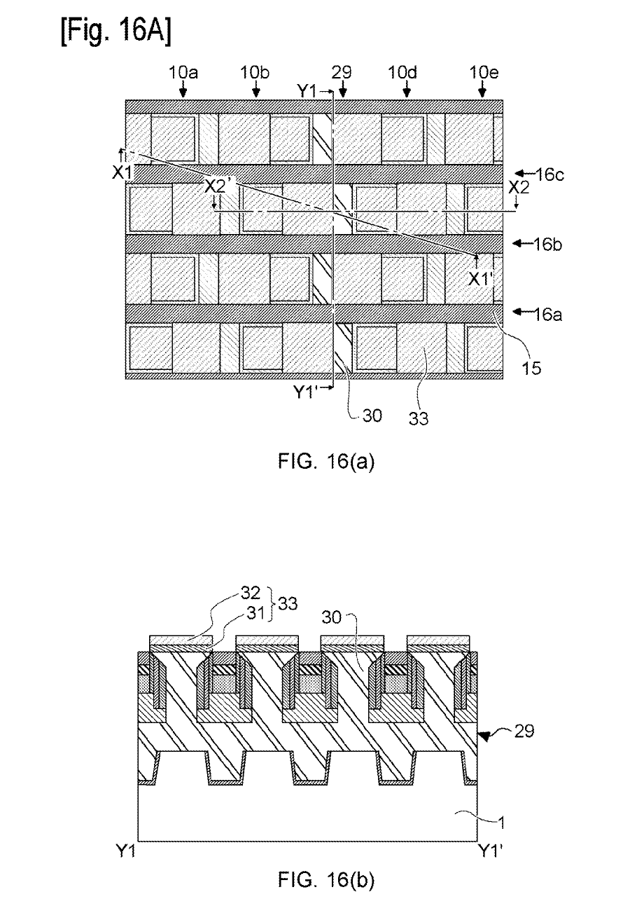

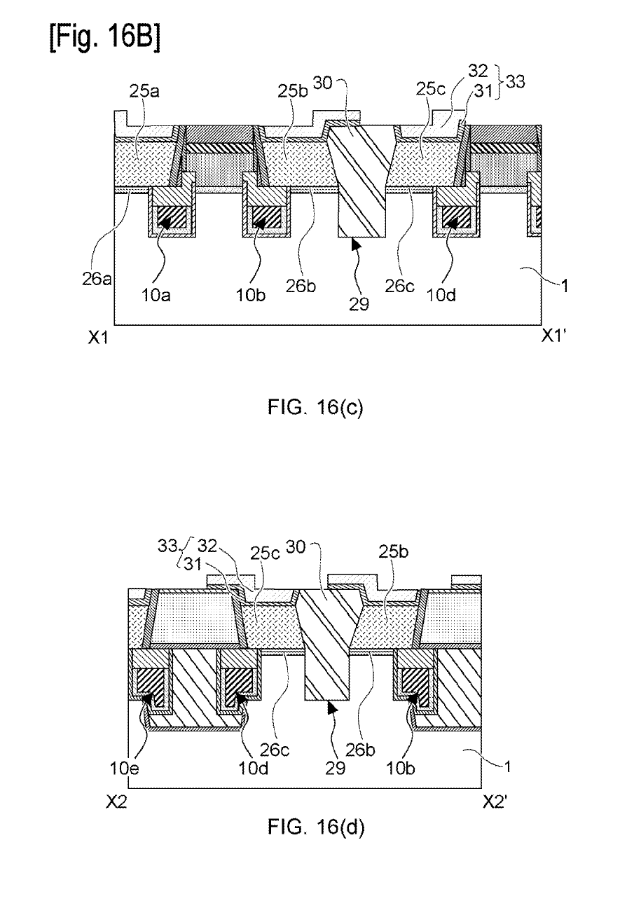

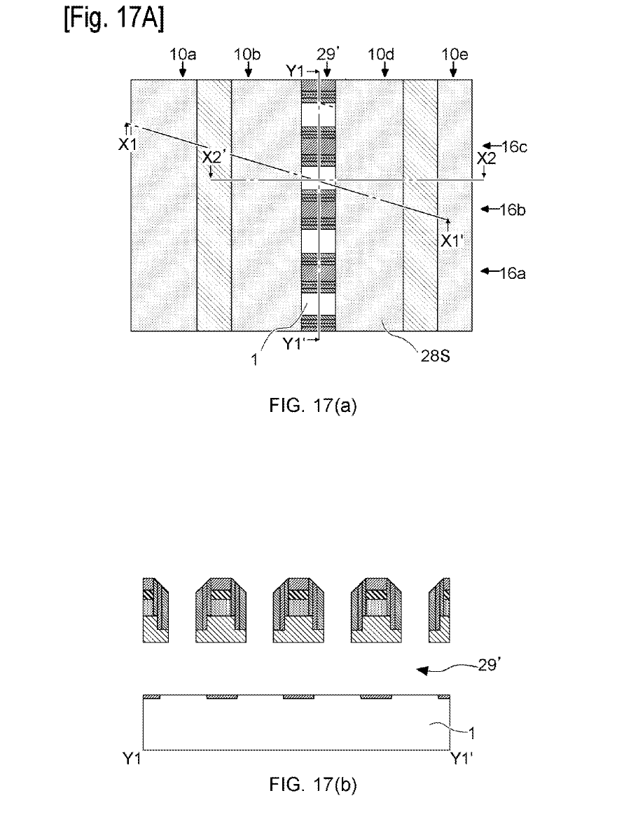

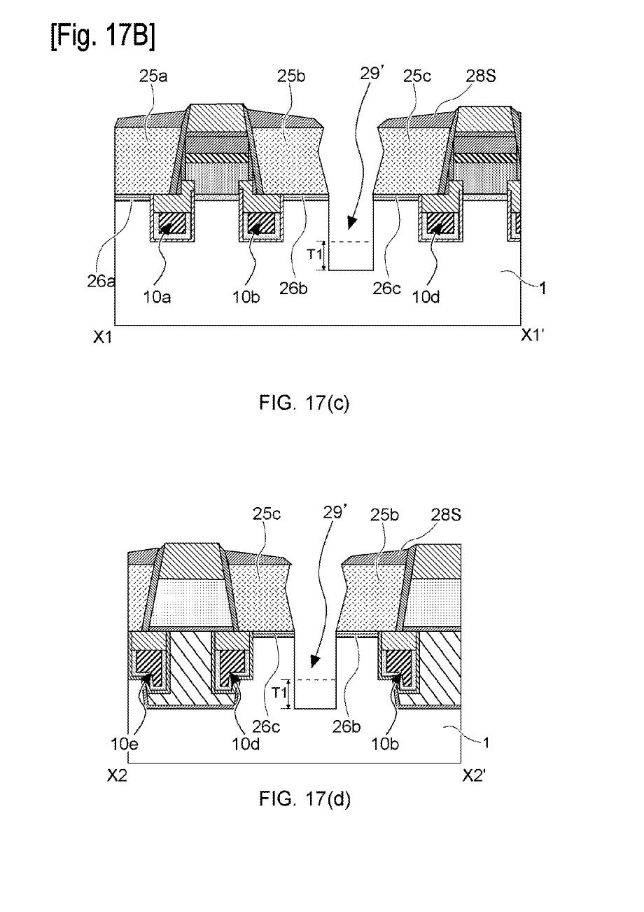

### BRIEF DESCRIPTION OF THE FIGURES

[FIG. 1A] FIG. 1(a) is a schematic plan view of a semiconductor device 100 according to an exemplary embodiment of the present invention;

[FIG. 1B] FIG. 1(b) is a view in the cross section Y1-Y1′ in FIG. 1(a);

[FIG. 1C] FIG. 1(c) is a view in the cross section X1-X1′ in FIG. 1(a);

[FIG. 1D] FIG. 1(d) is a view in the cross section X2-X2′ in FIG. 1(a);

[FIG. 2A] illustrates a step in the manufacture of the semiconductor device 100 shown in FIG. 1, where FIG. 2(a) is a schematic plan view, and FIG. 2(b) is a view in the cross section Y1-Y1′ in FIG. 2(a);

[FIG. 2B] FIG. 2(c) is a view in the cross section X1-X1′ in FIG. 2(a), and FIG. 2(d) is a view in the cross section X2-X2′ in FIG. 2(a);

[FIG. 3A] illustrates the process for manufacturing the semiconductor device 100 shown in FIG. 1, where FIG. 3(a) is a schematic plan view and FIG. 3(b) is a view in the cross section Y1-Y1′ in FIG. 3(a);

[FIG. 3B] FIG. 3(c) is a view in the cross section X1-X1′ in FIG. 3(a), and FIG. 3(d) is a view in the cross section X2-X2′ in FIG. 3(a);

[FIG. 4A] illustrates a step in the manufacture of the semiconductor device 100 shown in FIG. 1, where FIG. 4(a) is a schematic plan view and FIG. 4(b) is a view in the cross section Y1-Y1′ in FIG. 4(a);

[FIG. 4B] FIG. 4(c) is a view in the cross section X1-X1′ in FIG. 4(a), and FIG. 4(d) is a view in the cross section X2-X2′ in FIG. 4(a);

[FIG. 5A] illustrates a step in the manufacture of the semiconductor device 100 shown in FIG. 1, where FIG. 5(a) is a schematic plan view and FIG. 5(b) is a view in the cross section Y1-Y1′ in FIG. 5(a);

[FIG. 5B] FIG. 5(c) is a view in the cross section X1-X1′ in FIG. 5(a), and FIG. 5(d) is a view in the cross section X2-X2′ in FIG. 5(a);

[FIG. 6A] illustrates a step in the manufacture of the semiconductor device 100 shown in FIG. 1, where FIG. 6(a) is a schematic plan view and FIG. 6(b) is a view in the cross section Y1-Y1′ in FIG. 6(a);

[FIG. 6B] FIG. 6(c) is a view in the cross section X1-X1′ in FIG. 6(a), and FIG. 6(d) is a view in the cross section X2-X2′ in FIG. 6(a);

[FIG. 7A] illustrates a step in the manufacture of the semiconductor device 100 shown in FIG. 1, where FIG. 7(a) is a schematic plan view and FIG. 7(b) is a view in the cross section Y1-Y1′ in FIG. 7(a);

[FIG. 7B] FIG. 7(c) is a view in the cross section X1-X1′ in FIG. 7(a), and FIG. 7(d) is a view in the cross section X2-X2′ in FIG. 7(a);

[FIG. 8A] illustrates a step in the manufacture of the semiconductor device 100 shown in FIG. 1, where FIG. 8(a) is a schematic plan view and FIG. 8(b) is a view in the cross section Y1-Y1′ in FIG. 8(a);

[FIG. 8B] FIG. 8(c) is a view in the cross section X1-X1′ in FIG. 8(a), and FIG. 8(d) is a view in the cross section X2-X2′ in FIG. 8(a);

[FIG. 9A] illustrates a step in the manufacture of the semiconductor device 100 shown in FIG. 1, where FIG. 9(a) is a schematic plan view and FIG. 9(b) is a view in the cross section Y1-Y1′ in FIG. 9(a);

[FIG. 9B] FIG. 9(c) is a view in the cross section X1-X1′ in FIG. 9(a), and FIG. 9(d) is a view in the cross section X2-X2′ in FIG. 9(a);

[FIG. 10A] illustrates a step in the manufacture of the semiconductor device 100 shown in FIG. 1, where FIG. 10(a) is a schematic plan view and FIG. 10(b) is a view in the cross section Y1-Y1′ in FIG. 10(a);

[FIG. 10B] FIG. 10(c) is a view in the cross section X1-X1′ in FIG. 10(a), and FIG. 10(d) is a view in the cross section X2-X2′ in FIG. 10(a);

[FIG. 11A] illustrates a step in the manufacture of the semiconductor device 100 shown in FIG. 1, where FIG. 11(a) is a schematic plan view and FIG. 11(b) is a view in the cross section Y1-Y1′ in FIG. 11(a);

[FIG. 11B] FIG. 11(c) is a view in the cross section X1-X1′ in FIG. 11(a), and FIG. 11(d) is a view in the cross section X2-X2′ in FIG. 11(a);

[FIG. 12A] illustrates a step in the manufacture of the semiconductor device 100 shown in FIG. 1, where FIG. 12(a) is a schematic plan view and FIG. 12(b) is a view in the cross section Y1-Y1′ in FIG. 12(a);

[FIG. 12B] FIG. 12(c) is a view in the cross section X1-X1′ in FIG. 12(a), and FIG. 12(d) is a view in the cross section X2-X2′ in FIG. 12(a);

[FIG. 13A] illustrates a step in the manufacture of the semiconductor device 100 shown in FIG. 1, where FIG. 13(a) is a schematic plan view and FIG. 13(b) is a view in the cross section Y1-Y1′ in FIG. 13(a);

[FIG. 13B] FIG. 13(c) is a view in the cross section X1-X1′ in FIG. 13(a), and FIG. 13(d) is a view in the cross section X2-X2′ in FIG. 13(a);

[FIG. 14A] illustrates a step in the manufacture of the semiconductor device 100 shown in FIG. 1, where FIG. 14(a) is a schematic plan view and FIG. 14(b) is a view in the cross section Y1-Y1′ in FIG. 14(a);

[FIG. 14B] FIG. 14(c) is a view in the cross section X1-X1′ in FIG. 14(a), and FIG. 14(d) is a view in the cross section X2-X2′ in FIG. 14(a);

[FIG. 15A] illustrates a step in the manufacture of the semiconductor device 100 shown in FIG. 1, where FIG. 15(a) is a schematic plan view and FIG. 15(b) is a view in the cross section Y1-Y1′ in FIG. 15(a);

[FIG. 15B] FIG. 15(c) is a view in the cross section X1-X1′ in FIG. 15(a), and FIG. 15(d) is a view in the cross section X2-X2′ in FIG. 15(a);

[FIG. 16A] illustrates a step in the manufacture of the semiconductor device 100 shown in FIG. 1, where FIG. 16(a) is a schematic plan view and FIG. 16(b) is a view in the cross section Y1-Y1′ in FIG. 16(a);

[FIG. 16B] FIG. 16(c) is a view in the cross section X1-X1′ in FIG. 16(a), and FIG. 16(d) is a view in the cross section X2-X2′ in FIG. 16(a);

[FIG. 17A] illustrates a step in the manufacture of a semiconductor device 200 according to a different exemplary embodiment of the present invention, where FIG. 17(a) is a schematic plan view and FIG. 17(b) is a view in the cross section Y1-Y1′ in FIG. 17(a);

[FIG. 17B] FIG. 17(c) is a view in the cross section X1-X1′ in FIG. 17(a), and FIG. 17(d) is a view in the cross section X2-X2′ in FIG. 17(a);

[FIG. 18A] FIG. 18(a) is a schematic plan view of a semiconductor device 500 according to a conventional example, and FIG. 18(b) is a view in the cross section Y1-Y1′ in FIG. 18(a); and

[FIG. 18B] FIG. 18(c) and FIG. 18(d) are a view in the cross section X1-X1′ and the cross section X2-X2′, respectively, in FIG. 18(a).

### MODE OF EMBODIMENT OF THE INVENTION

Preferred exemplary embodiments of the present invention will be described below with reference to the figures, but the present invention is not limited just to these exemplary embodiments; also included are suitable modifications that can be made, as required, by a person skilled in the art, within the scope of the present invention.

### Exemplary Embodiment 1

A semiconductor device 100 according to this exemplary embodiment is a DRAM; FIG. 1(a) is a schematic plan view, FIG. 1(b) is a view in the cross section Y1-Y1′ in FIG. 1(a), FIG. 1(c) is a view in the cross section X1-X1′ in FIG. 1(a), and FIG. 1(d) is a view in the cross section X2-X2′ in FIG. 1(a). FIG. 2 to FIG. 16 are views in cross section of the series of steps in the manufacture of the semiconductor device 100 according to this exemplary embodiment, and in each sub-drawing (a) is a schematic plan view, (b) is a view in the cross section Y1-Y1′ in (a), (c) is a view in the cross section X1-X1′ in (a), and (d) is a view in the cross section X2-X2′ in (a).

The semiconductor device 100 according to this exemplary embodiment will be described first of all with reference to FIG. 1.

The semiconductor device 100 constitutes a DRAM memory cell. A plurality of element isolation regions 2 extending continuously in the X′-direction (first direction) and a plurality of active regions 1A likewise extending continuously in the X′-direction are disposed at equal intervals and an equal pitch alternately in the Y-direction (second direction) on a semiconductor substrate 1. The element isolation regions 2 are formed by an element isolation insulating film embedded in a trench. The following are disposed extending continuously in the Y-direction across the plurality of element isolation regions 2 and the plurality of active regions 1A: a first embedded word line (referred to below as a first word line) 10a, a second embedded word line (referred to below as a second word line) 10b, a third embedded word line (referred to below as a third word line) 10d, and a fourth embedded word line (referred to below as a fourth word line) 10e. Furthermore, a diffusion layer isolation trench 29 formed at the same time as a word line trench is formed is provided in such a way as to lie between the second word line 10b and the third word line 10d. A diffusion layer isolation insulating film 30 such as a silicon nitride film is embedded in the diffusion layer isolation trench 29, and has the function of dividing the continuous strip-like active regions 1A into a plurality of independent active regions. Specifically, the active region 1A positioned to the left of the diffusion layer isolation trench 29 forms a first active region 1Aa, while the active region 1A positioned to the right forms a second active region 1Ab. First to fourth bit lines (BL) 16a-16d are provided extending in the X-direction (third direction).

The first active region 1Aa comprises: a second capacitance contact region 27b disposed adjacently to the left of the diffusion layer isolation trench 29; the second word line 10b disposed adjacent to the second capacitance contact region 27b; a contact region 17c (third BL contact region) with a third BL 16c disposed adjacent to the second word line 10b; the first word line 10a disposed adjacent to the third BL contact region 17c; and a first capacitance contact region 27a disposed adjacent to the first word line 10a. The first capacitance contact region 27a, first word line 10a and third BL contact region 17c form a first cell transistor Tr1, and the third BL contact region 17c, second word line 10b and second capacitance contact region 27b form a second cell transistor Tr2.

The second active region 1Ab comprises: a third capacitance contact region 27c disposed adjacently to the right of the diffusion layer isolation trench 29; the third word line 10d disposed adjacent to the third capacitance contact region 27c; a contact region 17b (second BL contact region) with a second BL 16b disposed adjacent to the third word line 10d; the fourth word line 10e disposed adjacent to the second BL contact region 17b; and a fourth capacitance contact region (not depicted) disposed adjacent to the fourth word line 10e. The third capacitance contact region 27c, third word line 10d and second BL contact region 17b form a third cell transistor Tr3, and the second BL contact region 17b, fourth word line 10e and fourth capacitance contact region which is not depicted form a fourth cell transistor Tr4.

The memory cell according to this exemplary embodiment is constructed by arranging a plurality of first active regions 1Aa and second active regions 1Ab in the X-direction (third direction) with the diffusion layer isolation trench 29 interposed.

The first word line 10a, second word line 10b, third word line 10d and fourth word line 10e comprising a barrier film 7 and a metal film 8 such as tungsten are provided at the bottom of the respective trenches with the interposition of a gate insulating film 6 covering the inner surface of each word line trench also serving as a transistor gate electrode, provided on the semiconductor substrate 1. A cap insulating film 11 is provided by covering each word line and filling the respective trenches. A semiconductor pillar positioned to the left of the first word line 10a forms the first capacitance contact region 27a, and an impurity diffusion layer 26a forming either a source or drain is provided on the upper surface thereof. A semiconductor pillar positioned between the first word line 10a and the second word line 10b forms the third BL contact region 17c, and an impurity diffusion layer 12c forming the other of the source or drain is provided on the upper surface thereof. Furthermore, a semiconductor pillar positioned to the right of the second word line 10b forms the second capacitance contact region 27b, and an impurity diffusion layer 26b forming either a source or a drain is provided on the upper surface thereof. In addition, a semiconductor pillar positioned to the left of the third word line 10d forms the third capacitance contact region 27c, and an impurity diffusion layer 26c forming either a source or a drain is provided on the upper surface thereof. A semiconductor pillar positioned to the right of the third word line 10d then forms the second BL contact region 17b, and an impurity diffusion layer 12b forming the other of the source or drain is provided on the upper surface thereof.

The impurity diffusion layer 26a, gate insulating film 6, first word line 10a and impurity diffusion layer 12c form the first transistor Tr1 in the first active region 1Aa. Furthermore, the impurity diffusion layer 12c, gate insulating film 6, second word line 10b and impurity diffusion layer 26b form the second transistor Tr2. The cap insulating film 11 is provided in such a way as to cover the upper surfaces of the word lines 10a and 10b. The third BL 16c which is connected to the impurity diffusion layer 12c in the third BL contact region 17c is provided on the cap insulating film 11. The impurity diffusion layer 26c, gate insulating film 6, third word line 10d and impurity diffusion layer 12b form the third transistor Tr3 in the second active region 1Ab. Furthermore, the impurity diffusion layer 12b, gate insulating film 6, fourth word line 10e and impurity diffusion layer which is not depicted form the fourth transistor Tr4. The cap insulating film 11 is provided in such a way as to cover the upper surfaces of the word lines 10d and 10e. The second BL 16b which is connected to the impurity diffusion layer 12b in the second BL contact region 17b is provided on the cap insulating film 11.

In each bit line, a polysilicon layer 13 including a bit contact plug connected to an impurity diffusion layer, and a bit metal layer 14 formed thereon are provided, and a cover insulating film 15 is further provided on the upper surface thereof. Side walls 18 are provided on the lateral walls of each bit line, and a liner insulating film 19 is provided over the whole surface in such a way as to cover the bit lines. An embedded insulating film 20 filling the space of the recess formed between adjacent BL is provided on the liner insulating film 19. A capacitance contact 25 is provided passing through the embedded insulating film 20 and the liner film 19. The capacitance contact 25 connects first, second and third capacitance contact plugs 25a, 25b, 25c to the first, second and third capacitance contact regions 27a, 27b, 27c. The respective contact pads 33 are connected to the upper parts of the first, second and third capacitance contact plugs 25a, 25b, 25c. A stopper film 34 is provided in such a way as to cover the capacitance contact pads 33. A lower electrode 35 is provided on the capacitance contact pads 33. A capacitor is formed by providing a capacitance insulating film 36 continuously covering the from the inner wall to the outer wall surface of the lower electrode 35, and by providing an upper electrode 37 on the capacitance insulating film 36. The upper electrode 37 may comprise a stack of films, and a first upper electrode such as titanium nitride formed in a conformal manner on the capacitance insulating film 36, a filling layer (second upper electrode) such as doped polysilicon filling the space, and a plate electrode (third upper electrode) comprising a metal such as tungsten constituting a connection with upper layer wiring may also be included.

The abovementioned semiconductor device 100 has a structure in which element isolation in the first active region 1Aa and the second active region 1Ab is achieved by means of the diffusion layer isolation insulating film 30 embedded in the diffusion layer isolation trench 29, rather than by a field shield employing a dummy word line, as in the prior art. The diffusion layer isolation insulating film 30 differs with respect to the isolation inflating film 30′ which isolates the capacitance contacts in the conventional example, in that it is formed by filling as far as the diffusion layer isolation trench 29. The active regions are isolated by an insulating film in this way, and so miniaturization progresses, and it is possible to provide adequate element isolation even if the pitch narrows, problems in terms of an increase in PCBH defects are unlikely to occur, and it is possible to improve the yield.

The method for manufacturing the semiconductor device 100 shown in FIG. 1 will be described below with the aid of FIG. 2 to FIG. 16.

First of all, as shown in FIG. 2, element isolation regions 2 filled by an insulating film comprising a silicon dioxide film extending in a first direction (X′-direction) are formed on a semiconductor substrate 1 by means of a known STI process. As a result, active regions 1A which are enclosed by the element isolation regions 2 and comprise the semiconductor substrate 1 are formed. It should be noted that here, the element isolation regions 2 are depicted as a laminated structure comprising a liner nitride film 2a and a silicon dioxide film 2b but this is not limiting.

A pad oxide film 3 comprising a silicon dioxide film is then formed over the whole surface of the semiconductor substrate 1 and an N-well region and a P-well region (not depicted) are formed by a known method through the pad oxide film 3.

Next, as shown in FIG. 3, a silicon dioxide film or the like is deposited on the semiconductor substrate 1, and a hard mask 4 which extends in the Y-direction and serves to form a plurality of trenches 5 at given intervals is patterned using a resist (not depicted).

The semiconductor substrate 1 is then etched by means of dry etching to form the trenches 5. Two pairs of adjacent trenches (5a and 5b; 5d and 5e) from among the plurality of trenches 5 are word line trenches in the same way as conventionally, and a trench 5c between two trenches (between 5b and 5d) corresponds to a conventional dummy word line trench, but according to the present invention, the trench 5c is formed into a diffusion layer isolation trench 29 in a subsequent step. At this point, the silicon dioxide film of the element isolation regions 2 is etched more deeply than the silicon of the semiconductor substrate 1, whereby saddle fins 1B are formed, as shown in FIG. 3(b). It is not essential to form the saddle fins 1B, and the trench depths in the active regions 1A and the element isolation regions 2 may be substantially equal. As a result, the active regions 1A are divided into a first portion lying between the pair of trenches 5a and 5b (or 5d and 5e), and a second portion lying between the pair of trenches 5a or 5b and 5c. The first portion forms a region to which bit lines are connected, and the second portion forms a region to which capacitance contact plugs are connected.

After this, a gate insulating film 6 is formed on the active regions 1A of the semiconductor substrate 1 using thermal oxidation and nitriding processes or the like. A liner nitride film in the element isolation regions 2 is also partially oxidized by means of thermal oxidation, and the silicon dioxide film is converted to a silicon oxynitride film by means of a subsequent nitriding process. As a result, the gate insulating film 6 is formed in succession on the insulating film of the element isolation regions 2 and also on the hard mask 4.

As shown in FIG. 4, a barrier film 7 such as titanium nitride and a metal film 8 such as tungsten are further deposited by means of CVD, for example, and then etched back, whereby word lines 10a, 10b, 10d, 10e are formed within the trenches 5a, 5b, 5d, 5e. At this point, the dummy word line 10c is formed in the same way inside the trench 5c.

Next, as shown in FIG. 5, a liner film is formed by means of CVD, for example, using a silicon nitride film or the like, in such a way as to cover the remaining metal film 8 and the inner walls of the trenches 5a-5e, although this is not depicted. A silicon dioxide film is deposited on the liner film. After this, CMP is carried out in order to planarize the surface until the liner film is exposed. In addition, the exposed liner film is removed and the hard mask 4 and silicon dioxide film are etched back to a predetermined height. As a result, embedded word lines filled with a cap insulating film 11 are formed. The cap insulating film 11 may be formed in such a way as to cover the hard mask 4 when the remaining hard mask 4 is thin, and said film maintains sufficient distance between the bit lines formed in a subsequent step and a diffusion layer which connects the capacitance contact plugs.

Next, as shown in FIG. 6, part of the hard mask 4 is removed using a photolithography technique and a dry etching technique, and bit line contact regions are formed; in FIG. 7(b), a bit contact is formed which is connected to the upper surfaces of the third BL contact region 17c and the second BL contact region 17b. The bit contact is formed as a pattern with line-shaped openings extending in the same direction (the Y-direction) as the word lines 10. The surface (first portion) of the semiconductor substrate 1 is exposed at the region of intersection of the active regions with the pattern of the bit contact. After the bit contact has been formed, N-type impurity (arsenic or the like) is ion-implanted and an N-type impurity diffusion layer 12 is formed in the vicinity of the silicon surface. The N-type impurity diffusion layer 12 which has been formed functions as a transistor source/drain region. After this, a laminated film comprising a polysilicon film 13, a tungsten film 14 and a silicon nitride film 15 etc. is formed by means of CVD, for example. A line-shaped pattern is then formed extending in the direction intersecting the word lines 10 (the X-direction) using a photolithography technique and a dry etching technique, and bit lines 16 are formed. The polysilicon film 13 and the N-type impurity diffusion layer 12 under the bit lines are connected at the region of the silicon surface exposed inside the bit contact. In the portion shown in FIG. 6(c), the second BL 16b and the N-type impurity diffusion layer 12b are connected, and the third BL 16c and the N-type impurity diffusion layer 12c are connected.

Next, as shown in FIG. 7, a silicon nitride film 18 covering the side surfaces of the bit lines 16 is formed, after which etching is used to remove part of the silicon dioxide film hard mask 4, the pad oxide film 3 and the cap insulating film 11, and the surface of the cap insulating film 11 is etched back in such a way to have substantially the same height as the silicon surface of the semiconductor substrate 1. A liner film 19 covering the whole surface is then formed by a silicon nitride film or the like using CVD, for example.

A SOD film 20 which is a coating film is deposited in such a way as to fill the spaces between the bit lines, after which annealing is carried out in a high-temperature steam (H₂O) atmosphere in order to modify the film to a solid film. Planarization is carried out by means of CMP until the upper surface of the liner film 19 is exposed, after which a silicon dioxide film formed by CVD, for example, is formed as a cap silicon dioxide film 21 and the surface of the SOD film 20 is covered. A mask polysilicon film 22 is further formed on the cap silicon dioxide film 21.

Next, as shown in FIG. 8, a capacitance contact hole 23 is formed using a photolithography technique and a dry etching technique. Specifically, a line-shaped pattern is produced using a lithography technique and the cap silicon dioxide film 21 and mask polysilicon film 22 are formed into a capacitance contact hard mask. The capacitance contact hard mask is formed as a pattern with line shaped openings which extends in the same direction as the dummy word line 10c (the Y-direction) and opens over the dummy word line 10c.

The capacitance contact hole 23 is formed passing through the SOD film 20 and the line until 19 using a dry etching technique. The semiconductor substrate 1 (second portion) is exposed at the region of intersection of the capacitance contact hole 23 and the active region 1A. A silicon nitride film is then formed using CVD, for example, etch-back is performed, and a silicon nitride film side wall 24 is formed.

Next, as shown in FIG. 9, the inside of the capacitance contact hole 23 is filled with polysilicon doped with N-type impurity (phosphorus or the like) using CVD, for example. The polysilicon is then etched back and is left up to a height at which the inside of the capacitance contact hole 23 is not completely filled, and a polysilicon plug 25 is formed. Here, the mask polysilicon film 22 is also removed. N-type impurity diffusion layers 26a, 26b, 26c are formed by means of the N-type impurity doped in the polysilicon plug 25 in the vicinity of the surface of the capacitance contact regions 27a, 27b, 27c. The N-type impurity diffusion layers 26a, 26b, 26c which are formed function as a transistor source/drain region.

Next, as shown in FIG. 10, a silicon nitride film 28 is formed in such a way as to cover the polysilicon plug 25 remaining inside the capacitance contact hole.

Next, as shown in FIG. 11, the silicon nitride film 28 is etched back and a nitride film side wall 28S is formed. The polysilicon plug 25 is then dry etched using the nitride film side wall 28S as a mask. By this means, the second capacitance contact plug 25b connected to the second capacitance contact region 27b, and the third capacitance contact plug 25c connected to the third capacitance contact region 27c can be isolated in the X-direction. It should be noted that, in this state, the polysilicon plugs 25 are joined in the Y-direction on the bit lines 16 under the nitride film side wall 28S. The cap insulating film 11 of the dummy word line 10c is exposed between the second capacitance contact plug 25b and the third capacitance contact plug 25c. The method up to the step in FIG. 11 is the same as the steps in the manufacture of the semiconductor device 500 according to the conventional example shown in FIG. 18.

Here, according to this exemplary embodiment, as shown in FIG. 12, the cap insulating film 11 at the upper part of the dummy word line 10c is etched and removed using dry etching. In this process, part of the gate insulating film 6 may also be removed at the same time. FIGS. 12(c) and (d) show a situation in which part of the gate insulating film 6 has also been removed at the same time.

Next, as shown in FIG. 13, the barrier film 7 and metal film 8 inside the dummy word line 10c are removed by immersion in an etching solution comprising hydrogen peroxide solution, a chelating agent, an alkali hydroxide and an iodine compound. It is also possible to remove the barrier film 7 and the metal film 8 inside the dummy word line 10c below the bit lines 16 because of removal by immersion in the etching solution, as shown in FIG. 13(b). Furthermore, this etching solution does not etch polysilicon, so the polysilicon plug 25 is not etched. In addition, the gate insulating film 6 is also removed by immersion in a hydrofluoric acid solution. The silicon dioxide film 2b in the element isolation regions 2 below the bit lines 16 is also removed because of removal by immersion in the hydrofluoric acid solution, as shown in FIG. 13(b). In this way, the trench (5c) in which the dummy word line 10c was present forms a diffusion layer isolation trench 29 in which the semiconductor substrate 1 is exposed. At this point, the width of the diffusion layer isolation trench 29 in the element isolation regions 2 is greater than the width in the active regions. It should be noted that it is not essential to remove the gate insulating film 6 and the silicon dioxide film 2b in the element isolation region 2, and said films may remain as they are. In this case, the width of the diffusion layer isolation trench 29 in the element isolation region 2 is the same as the width in the active regions.

Next, as shown in FIG. 14, the diffusion layer isolation trench 29 is filled by a silicon nitride film or the like, and a diffusion layer isolation insulating film 30 is formed in such a way as to cover the side wall silicon nitride film 28S and the polysilicon plugs 25a, 25b, 25c. By filling the diffusion layer isolation trench 29 with a silicon nitride film, the silicon dioxide film 2b constituting an element isolation insulating film in the element isolation regions 2 is divided by the diffusion layer isolation insulating film 30 which is a silicon nitride film.

Next, as shown in FIG. 15, the diffusion layer isolation insulating film 30 and the side wall silicon nitride film 28S are polished by CMP, and planarization is carried out until the upper surface of the cap insulating film 15 on the bit lines 16 is exposed. As a result, the polysilicon plugs 25 are isolated in the Y-direction by the bit lines 16. After this, the polysilicon plugs 25 are etched back and the capacitance contact plugs 25a, 25b, 25c are completed by the polysilicon remaining at the lower part inside the capacitance contact hole 23.

Next, as shown in FIG. 16, a barrier film 31 such as titanium nitride and a wiring material layer such as a metal film 32 which is tungsten or the like are embedded using CVD in the region inside the capacitance contact hole in which the capacitance contact plugs 25 are not embedded. A capacitance contact pad 33 is then formed using a photolithography technique and a dry etching technique. A silicide film such as cobalt silicide may be formed on the upper surfaces of the capacitance contact plugs 25 in order to reduce the contact resistance with the capacitance contact pad 33.

After this, as shown in FIG. 1, a stopper film 34 is formed using a silicon nitride film in such a way as to cover the capacitance contact pad 33. A lower electrode 35 of a capacitor element is formed by titanium nitride or the like on the capacitance contact pad 33. A capacitance insulating film 36 is then formed in such a way as to cover the surface of the lower electrode 35, after which an upper electrode 37 of a capacitor element is formed by titanium nitride or the like. After this, multilayer wiring is formed by repeating a wiring formation step, although this is not depicted, and the semiconductor device 100 is formed.

The abovementioned exemplary embodiment of the method for manufacturing a semiconductor device relates to a structure in which element isolation in the first active region 1Aa and the second active region 1Ab is achieved by means of the diffusion layer isolation insulating film 30 embedded in the diffusion layer isolation trench 29, rather than by a field shield employing the dummy word line 10c, as in the prior art. Consequently, miniaturization progresses and it is possible to provide adequate element isolation even if the pitch narrows, problems in terms of an increase in PCBH defects are unlikely to occur, and it is possible to improve the yield.

It should be noted that in this exemplary embodiment, there is no need to etch back the polysilicon plugs 25 (FIG. 15) or to form the subsequent contact pad 33. According to the present invention, the contact plugs formed inside one contact hole 23, i.e. the two capacitance contact plugs (25b and 25c in the figures) facing each other in the X-direction with the diffusion layer isolation insulating film 30 therebetween employ the inclined surfaces of the capacitance contact hard mask and the distance between centers on the upper surfaces is greater than the distance between centers on the lower surfaces, so it is possible to maintain adequate spacing between capacitors even if the lower electrode of the capacitor is formed on the capacitance contact plug.

### Exemplary Embodiment 2

FIG. 17 shows the situation partway the steps in the manufacture of a semiconductor device 200 according to a preferred mode of embodiment of the present invention, where (a) is a schematic plan view, (b) is a view in the cross section Y1-Y1′ in (a), (c) is a view in the cross section X1-X1′ in (a), and (d) is a view in the cross section X2-X2′ in (a).

Referring to FIG. 17, word lines 10a, 10b, 10d, 10e also serving as transistor gate electrodes are provided on a semiconductor substrate 1. At this point, a diffusion layer isolation trench 29′ is also provided, said trench 29′ having a structure which is excavated at least to the same level as element isolation regions 2 extending in the X′-direction, or excavated to a deeper position, in comparison with the trench 29 (broken line) in Exemplary Embodiment 1. Specifically, the trench 29′ is excavated to a depth T1 below the bottom part of the trench 29 in Exemplary Embodiment 1. The engraving depth T1 of the diffusion layer isolation trench 29′ is preferably in the range of 100 nm to 160 nm, and in this exemplary embodiment, T1=150 nm. The inside of the trench 29′ is filled with a diffusion layer isolation insulating film 30 such as silicon nitride.

Specifically, after the steps up to FIG. 13 in Exemplary Embodiment 1 have been implemented, the diffusion layer isolation trench 29 in which the semiconductor substrate 1 is exposed is etched using dry etching, and the semiconductor substrate 1 is etched up to the depth T1=150 nm. The etching depth T1 of the diffusion layer isolation trench 29′ is preferably in the range of 100 nm to 160 nm. A situation is shown here in which part of the semiconductor substrate 1 in contact with the element isolation regions 2 is at a higher level than the bottom part of the diffusion layer isolation trench 29′ and remains at a position at the bottom part of the diffusion layer isolation trench 29, but etching with somewhat enhanced isotropy may be carried out so that the bottom part in the element isolation regions and the bottom part in the active regions are substantially continuous. The subsequent steps are the same as in FIG. 14 to FIG. 16 of Exemplary Embodiment 1.

With the semiconductor device 200 according to this exemplary embodiment, the diffusion layer isolation trench 29′ which is excavated up to a deeper position than in Exemplary Embodiment 1 is formed. Miniaturization therefore progresses further than in Exemplary Embodiment 1, and it is possible to provide adequate element isolation even if the pitch narrows, problems in terms of an increase in PCBH defects are unlikely to occur, and it is possible to improve the yield.

### KEY TO SYMBOLS

1 . . . Semiconductor substrate

1A . . . Active region

1Aa . . . First active region

1Ab . . . Second active region

1B . . . Saddle fin

2 . . . Element isolation region

2a . . . Liner nitride film

2b . . . Silicon dioxide film

3 . . . Pad oxide film

4 . . . Hard mask

5 . . . Word line trench

6 . . . Gate insulating film

7 . . . Barrier film

8 . . . Metal film

10a, 10b, 10d, 10e . . . Word line

10c . . . Dummy word line

11 . . . Cap insulating film

12 . . . N-type impurity diffusion layer

13 . . . Polysilicon film

14 . . . Tungsten film

15 . . . Silicon nitride film

16 . . . Bit line

17 . . . Bit line contact region

18 . . . Silicon nitride film

19 . . . Liner film

20 . . . SOD film

21 . . . Cap silicon dioxide film

22 . . . Mask polysilicon film

23 . . . Capacitance contact hole

24 . . . Nitride film side wall

25 . . . Polysilicon plug

26a-26c . . . N-type impurity diffusion layer

27a-27c . . . Capacitance contact region

28 . . . Silicon nitride film

29 . . . Diffusion layer isolation trench

30 . . . Diffusion layer isolation insulating film

31 . . . Barrier film

32 . . . Metal film

33 . . . Capacitance contact pad

34 . . . Stopper film

35 . . . Lower electrode

36 . . . Capacitance insulating film

37 . . . Upper electrode

100, 200 . . . Semiconductor device

1. A semiconductor device comprising:
a plurality of element isolation regions extending in a first direction on a semiconductor substrate;
an active region lying between the element isolation regions and extending in the first direction;
a plurality of trenches disposed at predetermined intervals and extending in a second direction intersecting the first direction;
a pair of embedded word lines embedded inside two adjacent trenches with one of the abovementioned trenches interposed;
a bit line which extends in a third direction different than the first and second directions and is connected to an active region between the pair of embedded word lines;
a contact which is connected to an active region facing an active region to which the bit line is connected with the pair of embedded word lines interposed; and
a diffusion layer isolation insulating film which is embedded in the trench between the pair of embedded word lines, and insulates and isolates the contact on both sides of said trench and a diffusion layer in the active region connected to the contact.

2. The semiconductor device as claimed in claim 1, wherein the depth of the trenches in the element isolation regions is greater than the depth in the active region.

3. The semiconductor device as claimed in claim 1, wherein the depth of the trench in which the diffusion layer isolation insulating film is embedded is greater than the depth of the trench in which the embedded word lines are embedded in a range of between 100 nm and 160 nm, in at least the active region.

4. The semiconductor device as claimed in claim 3, wherein the depth of the trench in which the diffusion layer isolation insulating film is embedded in the active region is substantially equal to the depth of the trench in which the diffusion layer isolation insulating film is embedded in the element isolation regions.

5. The semiconductor device as claimed in claim 1, wherein the trench in which the diffusion layer isolation insulating film is embedded is wider in the element isolation regions than in the active region.

6. The semiconductor device as claimed in claim 1, wherein the element isolation regions comprise a silicon dioxide film, and the silicon dioxide film is divided by the diffusion layer isolation insulating film in the trench in which the diffusion layer isolation inflating film is embedded.

7. The semiconductor device as claimed in claim 6, wherein the diffusion layer isolation insulating film comprises a silicon nitride film.

8. The semiconductor device as claimed in claim 1, wherein the distance between centers on the upper surfaces of the two contacts which are facing in the third direction with the diffusion layer isolation insulating film interposed is greater than the distance between centers on the lower surfaces.

9. The semiconductor device as claimed in claim 8, comprising a capacitance contact part on the upper surface of the contact, and a capacitor provided with a lower electrode connected to the capacitance contact plug and an upper electrode facing the lower electrode with a capacitance insulating film interposed.

10. A method for manufacturing a semiconductor device, comprising:
forming a plurality of element isolation regions extending in a first direction on a semiconductor substrate, and defining an active region extending in the first direction between the element isolation regions;
forming two adjacent pairs of word line trenches extending in a second direction intersecting the first direction, and a diffusion layer isolation trench between the pairs of word line trenches on the semiconductor substrate with a predetermined gap therebetween as a plurality of trenches which are shallower than the element isolation regions, and dividing the active region into a first portion lying between the two word line trenches, and a second portion lying between the word line trench and the diffusion layer isolation trench;
embedding a first conductive material inside the plurality of trenches with a gate insulating film interposed;
etching back the first conductive material as far as a position at a lower level than the surface of the semiconductor substrate, and forming a dummy word line between the two pairs of word lines and the pair of word lines;
forming an insulating film which fills the trench on the word line and the dummy word line;
forming, on the abovementioned insulating film, a bit line which is connected to the first portion, extends in a third direction different than the first and second directions and comprises an upper insulating film;
forming a mask pattern extending in the second direction on the two pairs of word lines, wherein the active region in the second portion on both sides of the dummy word line is exposed, and a contact hole which is defined by the area between the bit lines and the area between the mask patterns is formed;
filling the contact hole by embedding a second conductive material as far as a position at a lower level than the upper part of the mask pattern;
forming side walls on the lateral walls of the mask pattern and the upper surface of the second conductive material on the dummy word line is exposed and opened;
etching the second conductive material using the side walls as a mask, and the embedded insulating film at the upper part of the dummy word line is exposed;
removing the insulating film by dry etching and the exposed first conductive material is further removed by wet etching to form a diffusion layer isolation trench;
forming a diffusion layer isolation insulating film over the whole surface by filling the diffusion layer isolation trench; and
etching the diffusion layer isolation insulating film back in such a way that the mask pattern and the second conductive material are exposed, after which the second conductive material is etched back to a height which is no greater than the upper insulating film of the bit line, and a contact plug comprising the second conductive material which is insulated and isolated by the diffusion layer isolation insulating film is formed inside the contact hole.

11. The method for manufacturing a semiconductor device as claimed in claim 10, in which the diffusion layer isolation trench is formed by removing part of the insulating film in the element isolation regions at the bottom of a dummy gate trench.

12. The method for manufacturing a semiconductor device as claimed in claim 10, wherein the diffusion layer isolation trench is formed by further etching the semiconductor substrate at the bottom of the dummy gate trench.

13. The method for manufacturing a semiconductor device as claimed in claim 12, in which the diffusion layer isolation trench is etched in such a way as to be deeper than the word line trench in a range of between 100 nm and 160 nm.

14. The method for manufacturing a semiconductor device as claimed in claim 10, wherein the diffusion layer isolation insulating film comprises a silicon nitride film.

15. The method for manufacturing a semiconductor device as claimed in claim 10, wherein in which the mask pattern is formed with an inclined shape such that the contact hole expands from the bottom part to the upper part in the third direction.

16. The method for manufacturing a semiconductor device as claimed in claim 10, wherein the third direction is orthogonal to the second direction.

17. The method for manufacturing a semiconductor device as claimed in claim 10, wherein forming the contact plug comprises etching the diffusion layer isolation insulating film, the mask pattern and the second conductive material arc etched back to the height of the upper insulating film of the bit line.

18. The method for manufacturing a semiconductor device as claimed in claim 17, comprising:
further etching the upper surface of the contact plug isolated by the diffusion layer isolation insulating film back so as to be at a lower level than the upper surface of the insulating film on the bit line and the mask pattern upper surface; and
forming a film of a third conductive material over the whole surface, dividing the third conductive material in the second direction by the bit line, and forming a contact pad partly extending over the mask pattern or the diffusion layer isolation insulating film.

19. The method for manufacturing a semiconductor device as claimed in claim 18, comprising forming a capacitor, wherein the capacitor comprises a lower electrode connected to the contact pad and an upper electrode facing the lower electrode with a capacitance insulating film interposed.
